(19) United States
(12) Patent Application Publication
(10) Pub. No.: US 2024/0403510 A1
(43) Pub. Date: Dec. 5, 2024

(54) PRODUCTION SYSTEM WITH COMPARISON BETWEEN REAL AND VIRTUAL SPACE

(71) Applicant: KABUSHIKI KAISHA YASKAWA DENKI, Kitakyushu-shi (JP)

(72) Inventors: Takeshi YAMASHITA, Fukuoka (JP); Yukio HASHIGUCHI, Fukuoka (JP); Yoshifumi ONOYAMA, Fukuoka (JP)

(21) Appl. No.: 18/798,829

(22) Filed: Aug. 9, 2024

Related U.S. Application Data
(63) Continuation of application No. PCT/JP2023/005317, filed on Feb. 15, 2023.
(60) Provisional application No. 63/310,554, filed on Feb. 15, 2022.

(51) Int. Cl. G06F 30/17

(52) U.S. Cl. CPC G06F 30/17

(57) ABSTRACT

A production system includes: a production device configured to perform, to produce a product, processing on a workpiece in a real space in response to a production instruction transmitted based on a production plan; and simulation circuitry configured to: cause a virtual production device to perform, in a virtual space, virtual processing corresponding to the processing in response to the transmitted production instruction; and compare an execution result of the processing with an execution result of the virtual processing.

### CROSS-REFERENCE TO RELATED APPLICATIONS

This application is a continuation application of PCT Application No. PCT/JP2023/005317, filed on Feb. 15, 2023, which claims the benefit of priority from U.S. Provisional Patent Application No. 63/310,554, filed on Feb. 15, 2022. The entire contents of the above listed PCT and priority applications are incorporated herein by reference.

### BACKGROUND

### Field

The present disclosure relates to a production system and a production method.

### Description of the Related Art

Japanese Unexamined Patent Publication No. 2021-86393 discloses a control system including a plurality of local controllers that respectively control a plurality of local devices including at least a robot, and an environment management unit that can communicate with the plurality of local controllers. The environment management unit includes an environmental information storage unit that stores environmental information, and an information update unit that updates the environmental information in accordance with the operations of the plurality of local devices. Each of the plurality of local controllers includes a condition monitoring unit that monitors whether the environmental information stored in the environmental information storage unit satisfies a predetermined condition, and an operation execution unit that causes the local device to be controlled to perform a predetermined operation if the environmental information satisfies the predetermined condition.

### SUMMARY

Disclosed herein is a production system. The production system may include: a production device configured to perform, to produce a product, processing on a workpiece in a real space in response to a production instruction transmitted based on a production plan; and simulation circuitry configured to: cause a virtual production device to perform, in a virtual space, virtual processing corresponding to the processing in response to the transmitted production instruction; and compare an execution result of the processing with an execution result of the virtual processing.

Additionally, a production method is disclosed herein. The production method may include: executing, to produce a product, processing on a workpiece in a real space in response to a production instruction transmitted based on a production plan; causing a virtual production device to perform, in a virtual space, virtual processing corresponding to the processing in response to the transmitted production instruction; and comparing an execution result of the processing with an execution result of the virtual processing.

### BRIEF DESCRIPTION OF THE DRAWINGS

FIG. 1 is a schematic diagram illustrating an example configuration of a production system.

FIG. 2 is a schematic diagram illustrating an example configuration of a production device.

FIG. 3 is a schematic diagram illustrating an example configuration of a robot.

FIG. 4 is a block diagram illustrating an example functional configuration of a host controller and a local controller.

FIG. 5 is a block diagram illustrating an example functional configuration of a virtual production device.

FIG. 6 is a block diagram illustrating a modification of the production system.

FIG. 7 is a block diagram illustrating another modification of the production system.

FIG. 8 is a block diagram illustrating still another modification of the production system.

FIG. 9 is a block diagram illustrating an example hardware configuration of a data collection device, a cell simulator, a host controller, and a local controller.

FIG. 10 is a sequence chart illustrating an example production procedure.

FIG. 11 is a flowchart illustrating an example execution procedure of processing.

FIG. 12 is a flowchart illustrating an example execution procedure of the processing.

FIG. 13 is a flowchart illustrating an example execution procedure of virtual processing.

FIG. 14 is a flowchart illustrating an example execution procedure of the virtual processing.

FIG. 15 is a flowchart illustrating an example unplanned processing procedure.

FIG. 16 is a flowchart illustrating an example service processing procedure.

### DETAILED DESCRIPTION

In the following description, with reference to the drawings, the same reference numbers are assigned to the same components or to similar components having the same function, and overlapping description is omitted.

### Production System

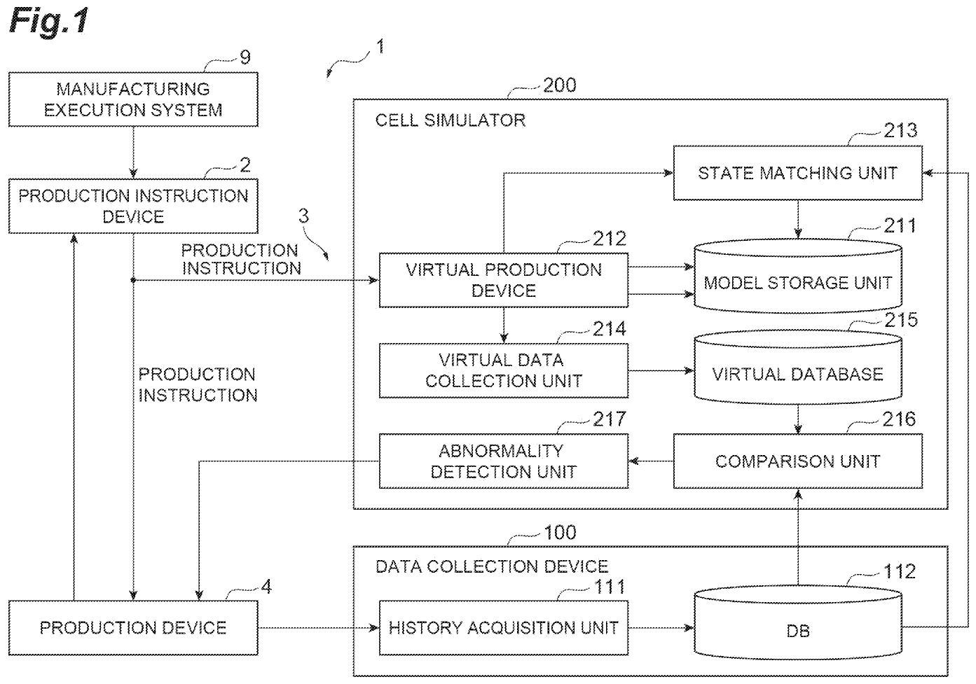

A production system 1 illustrated in FIG. 1 is a system for producing a product in a real space. The product may be any tangible object that is produced by machining or assembling one or more parts. The real space is a space in which a tangible object actually exists.

In order to flexibly operate the production system, the production device may autonomously determine how to allocate processing in accordance with the production instruction from a host controller to a plurality of machines and at what timing the plurality of machines are caused to perform the allocated processing, and autonomously operates based on the determination result. However, in a system in which the production device autonomously performs the processing based on the production instruction, operations to be performed by the production device varies depending on the combination of the state of the real space at the time of acquiring the production instruction and the content of the production instruction. For this reason, it is difficult to set correct operation contents in advance for all of the operation contents that the production device can actually perform, and to verify the operation contents of the production device in real time by comparing the operation contents with the correct operation contents.

On the other hand, the production system 1 may verify the autonomous operation of a production device in real time by utilizing so-called digital twin technology. The production system 1 includes a production device, a simulator, and a comparison unit. The production device produces a product by executing the processing on a workpiece in a real space based on a production instruction transmitted based on a production plan. The simulator includes a virtual production device configured to perform, in a virtual space based on the production instruction, virtual processing corresponding to the processing performed by the production device. The comparison unit is configured to compare an execution result of the processing with an execution result of the virtual processing.

The simulator performs the virtual processing based on the same production instruction as the production instruction on which the production device is based. That the production instructions are the same means that the contents of the production instructions are the same and the transmission timings of the production instructions are the same. For example, the simulator receives the production instruction after the production instruction is transmitted to the production device, and performs the virtual processing based on the received production instruction.

The simulator may perform the virtual processing in a period at least partially overlapping a period in which the production device performs the processing, but the execution timing of the processing and the execution timing of the virtual processing may not coincide with each other. For example, the simulator may perform the virtual processing after receiving the production instruction and before the production device performs the processing.

According to the production system 1, the execution result of the virtual processing corresponding to a situation in which the production device performs the processing is generated as the comparison reference by the simulator, and the execution result of the processing can be monitored in a timely manner based on the comparison with the comparison reference. Accordingly, the autonomous operation of the production device may be verified in real time.

As illustrated in FIG. 1, the production system 1 includes a production instruction device 2 and one or more cells 3. The production instruction device 2 breaks down a production plan generated by a manufacturing execution system (MES) 9 into a cell-based production plan, and transmits production instructions based on the cell-based production plan to each of the one or more cells 3.

Although one cell 3 is illustrated in FIG. 1, the production system 1 may include a plurality of cells 3. The production instruction device 2 transmits a production instruction to each of the plurality of cells 3. The cell 3 includes a production device 4, a data collection device 100, and a cell simulator 200. As will be described later, the production device 4, the data collection device 100, and the cell simulator 200 transmit and receive information to and from each other through network communication or the like.

The production device 4 produces the product by executing the processing on a workpiece in the real space based on the production instruction transmitted from the production instruction device 2 based on the production plan. The workpiece is a tangible object handled by the production device 4 to constitute at least a part of the product. For example, the workpiece may be a component assembled to the product, may be an intermediate product configured by assembly of components, or may be the finally completed product itself.

The processing for the workpiece includes a plurality of processes. Examples of the plurality of processes include loading a base part into a work area, assembling a part to the base part, fixing a part to the base part by fastening, welding, or the like, and unloading a product completed by assembling one or more parts to the base part from the work area.

As will be described later, the production device 4 includes a plurality of machines including at least one robot. Examples of the machine other than the robot include, but are not limited to, a transfer device that conveys a workpiece, a device that adjusts the position and posture of a workpiece to be worked, and a machine tool that performs machining on a workpiece. Any machine capable of executing a process on a workpiece may be included in the plurality of machines.

The plurality of processes may include two or more processes to be sequentially performed in series, and may include two or more processes which can be simultaneously performed by a plurality of machines. Examples of the processes performed by the robot include conveyance of a workpiece, assembly of a workpiece, fixation of a workpiece by fastening or the like, and loading and unloading of a workpiece into and out of a peripheral machine such as a machine tool. Examples of the processes performed by the machine tool include opening and closing of a door, chucking of a loaded workpiece, rotation and movement of the workpiece, tool replacement, arrangement and movement of a tool with respect to the workpiece, and release of the chuck after machining.

The data collection device 100 collects and accumulates data from the production device 4. For example, the data collection device 100 includes a history acquisition unit 111 and a database 112 as its functional constituent elements (hereinafter referred to as “functional blocks”). As an example of the data, the history acquisition unit 111 collects an execution history of the processing from the production device 4 and stores the history in the database 112.

The execution history of the processing is, for example, transition of the state of the real space due to the execution of the processing. The state of the real space is, for example, a state of the cell 3 in the real space, and includes a state of each of the plurality of machines and a state of the workpiece. Examples of the state of the robot include a joint angle of the robot, a type of a tool attached to the robot, and an operation state of the tool. Examples of the state of the machine tool include a state of a door, presence or absence of a workpiece, and a progress state of machining.

Examples of the state of the workpiece include an arrangement of the workpiece, a progress state of the processes for the workpiece, and the like. When the production device produces a plurality of products of the same type, the state of the real space may include the state of the workpiece for each of the plurality of products.

The production device 4 periodically acquires information indicating the state of the real space. The history acquisition unit 111 sequentially acquires the information acquired by the production device 4 and stores the information in the database 112 in association with the time. As a result, the execution history in which the transitions of the plurality of types of information are represented by the common time is accumulated in the database 112. The information indicating the state of the real space may include still picture data or moving picture data of the real space recorded by a camera or the like.

Note that the processing content by the functional block corresponds to the processing content of an entity having the functional block. For example, collecting and storing the execution history of the processing in the database 112 by the history acquisition unit 111 is equivalent to collecting and storing the execution history of the processing by the data collection device 100. The same applies to the following.

The cell simulator 200 is the above-described simulator and includes a model storage unit 211, a virtual production device 212, a state matching unit 213, a virtual data collection unit 214, a virtual database 215, a comparison unit 216, and an abnormality detection unit 217 as functional blocks. The model storage unit 211 stores at least models of the plurality of machines. The model is numerical data representing an arrangement, a structure, a shape, a size, and the like in the real space.

Based on the model, a change in the state of the machine due to the operation may be calculated without actually operating the machine. The model storage unit 211 may further store a model of the workpiece.

The virtual production device 212 performs the virtual processing in the virtual space based on the same production instruction as the production instruction on which the production device is based. The virtual processing includes a plurality of virtual processes having the same contents as the contents of the plurality of processes included in the processing. For example, the virtual production device 212 causes a plurality of virtual machines to operate in the virtual space based on the production instruction so as to correspond to the operation of the plurality of machines based on the production instruction. The plurality of virtual machines are, for example, models of the plurality of machines stored in the model storage unit 211.

Operating the plurality of virtual machines in the virtual space means calculating the numerical data representing the states of the plurality of machines after the operation based on the model without actually operating the plurality of machines. For example, it can be said that the numerical data representing the states of the plurality of machines after the operation is a plurality of virtual machines in the virtual space. A coordinate serving as a reference of the numerical data representing the states of the plurality of machines after the operation is the virtual space.

The virtual production device 212 may change, in the virtual space, a state of a virtual workpiece corresponding to the workpiece in accordance with the operation of the virtual machine in the virtual space. Changing the state of the virtual workpiece in the virtual space means calculating the numerical data representing the state of the workpiece after the operation based on the model without actually operating the machine. For example, it can be said that the numerical data representing the state of the workpiece after the operation is the virtual workpiece.

The state matching unit 213 matches the state of the virtual space with the state of the real space when the execution of the processing is started. For example, the state matching unit 213 matches the state of the virtual space with the state of the real space based on the information stored in the database 112 of the data collection device 100. The state of the virtual space is, for example, a state of a virtual cell corresponding to the cell 3 in the virtual space. For example, the state matching unit 213 matches the states of a plurality of virtual machines and a virtual workpiece in the virtual space with the states of the plurality of machines and the workpiece in the real space. Matching the states of the plurality of virtual machines and the virtual workpiece in the virtual space with the states of the plurality of machines and the workpiece in the real space means matching initial data serving as a reference for calculating the above-described “numerical data representing the states of the plurality of machines after operation” with “numerical data representing the state of the workpiece after operation” to the states of the plurality of machines and the workpiece in the real space.

The state matching unit 213 may match the state of the virtual space with the state of the real space in response to receiving the production instruction. The state matching unit 213 may repeatedly match the state of the virtual space with the state of the real space in a period other than a period in which the virtual production device 212 performs the virtual processing.

The virtual production device 212 performs the virtual processing based on the state of the virtual space matched with the state of the real space. By matching the state of the virtual space with the state of the real space immediately before the execution of the processing in accordance with the production instruction and then causing the virtual production device to perform the virtual processing, a comparison reference with reliability can be generated.

The virtual data collection unit 214 collects execution history of the virtual processing and stores the execution history in the virtual database 215. The execution history of the virtual processing is, for example, transition of the state of the virtual space due to the execution of the virtual processing. The state of the virtual space is, for example, a state of a virtual cell in the virtual space, and includes the state of each of the plurality of virtual machines and the state of the virtual workpiece.

The virtual production device 212 periodically calculates numerical data representing the state of the virtual space in accordance with the elapsed time while increasing the elapsed time from the start of the virtual processing. Note that the elapsed time is not a calculation time by the virtual production device 212, but a time obtained by simulating an elapsed time in the real space. The virtual data collection unit 214 sequentially acquires the numerical data calculated by the virtual production device 212, and stores them in the virtual database 215 in association with the elapsed time. Accordingly, the execution history in which the transitions of a plurality of types of information are represented by a common time is accumulated in the virtual database 215.

The comparison unit 216 compares the execution result of the processing with the execution result of the virtual processing. For example, the comparison unit 216 compares the execution history of the processing stored in the database 112 with the execution history of the virtual processing stored in the virtual database 215. For example, the comparison unit 216 compares the transition timing of the state of the real space based on the start time point of the processing with the transition timing of the state of the virtual space based on the start time point of the virtual processing. Examples of the transition timing of the states of the real space and the virtual space include a transition timing of the states of the plurality of machines and the plurality of virtual machines, and the transition timing of the states of the workpiece and the virtual workpiece. The transition timing means a timing at which a state changes.

The comparison between the execution result of the processing and the execution result of the virtual processing may not be limited to the comparison between the transition timings. The comparison unit 216 may compare the states of the plurality of machines and the states of the plurality of virtual machines at a time point at which the same time elapses from a reference. Examples of the comparison between the state of the machine and the state of the virtual machine include a comparison between a joint angle of the robot and a joint angle of the virtual robot, a comparison between a joint torque of the robot and a joint torque of the virtual robot, and the like.

The comparison unit 216 may compare the state of the workpiece and the state of the virtual workpiece at a point in time when the same time elapses from a reference. Examples of the comparison between the state of the workpiece and the state of the virtual workpiece include a comparison between an arrangement of the workpiece and an arrangement of the virtual workpiece, and a comparison between progress of the processes for the workpiece and progress of the processes for the virtual workpiece.

The abnormality detection unit 217 detects an abnormality of the production device 4 based on the comparison result by the comparison unit 216. For example, when a deviation satisfying a predetermined condition is detected between the execution result of the processing and the execution result of the virtual processing, the abnormality detection unit 217 detects the abnormality of the production device 4. As an example, the abnormality detection unit 217 detects the abnormality of the production device 4 when the difference between the transition timing of the state of the real space and the transition timing of the state of the virtual space exceeds a predetermined value.

The production device 4 may autonomously perform the processing with a predetermined algorithm based on the production instruction and the state of the real space. Correspondingly, the virtual production device 212 may autonomously perform the virtual processing with the above algorithm based on the production instruction and the state of the virtual space. By executing the virtual processing with the same algorithm as the algorithm of the production device based on the same production instruction as the production instruction for the production device, a more reliable comparison reference can be generated.

Autonomously executing the processing means that at least one of an operation to be performed by each of the plurality of machines for executing the processing and an operation timing of each of the plurality of machines is determined by itself based on the state of the real space.

For example, the production instruction may include an instruction on the type and quantity of product to be produced. The production device 4 may autonomously determine at least a part of an operation to be performed by each of the plurality of machines for a selected process by an algorithm for correcting at least the part of the operation to be performed by each of the plurality of machines so as to avoid a collision with a surrounding object based on the state of the real space. Similarly, the virtual production device 212 may autonomously determine at least a part of an operation to be performed by each of the plurality of virtual machines for a selected virtual process by an algorithm for correcting at least a part of the operation to be performed by each of the plurality of virtual machines so as to avoid a collision with a surrounding object based on the state of the virtual space.

The production device 4 may autonomously determine at least a part of an operation timing of each of the plurality of machines by an algorithm that determines whether an operation of each of the plurality of machines can be performed based on a predetermined condition and the state of the real space. Similarly, the virtual production device 212 may autonomously determine at least a part of an operation timing of each of the plurality of virtual machines by an algorithm for determining whether the operation of each of the plurality of virtual machines is executable based on a predetermined condition and the state of the virtual space.

Autonomously executing the processing may further include autonomously selecting a process to be performed by each of the plurality of machines from a plurality of processes included in the processing. For example, the production device 4 may autonomously select a process to be performed by each of the plurality of machines by an algorithm for specifying a process to be performed by each of the plurality of machines based on a type of a process executable by each of the plurality of machines, the state of each of the plurality of machines, and progress of the plurality of processes. Similarly, the virtual production device 212 may autonomously select a process to be performed by each of the plurality of virtual machines by an algorithm for specifying a virtual process to be performed by each of the plurality of virtual machines based on the type of a virtual process executable by each of the plurality of virtual machines, the state of each of the plurality of virtual machines, and progress of the plurality of virtual processes. Production Device

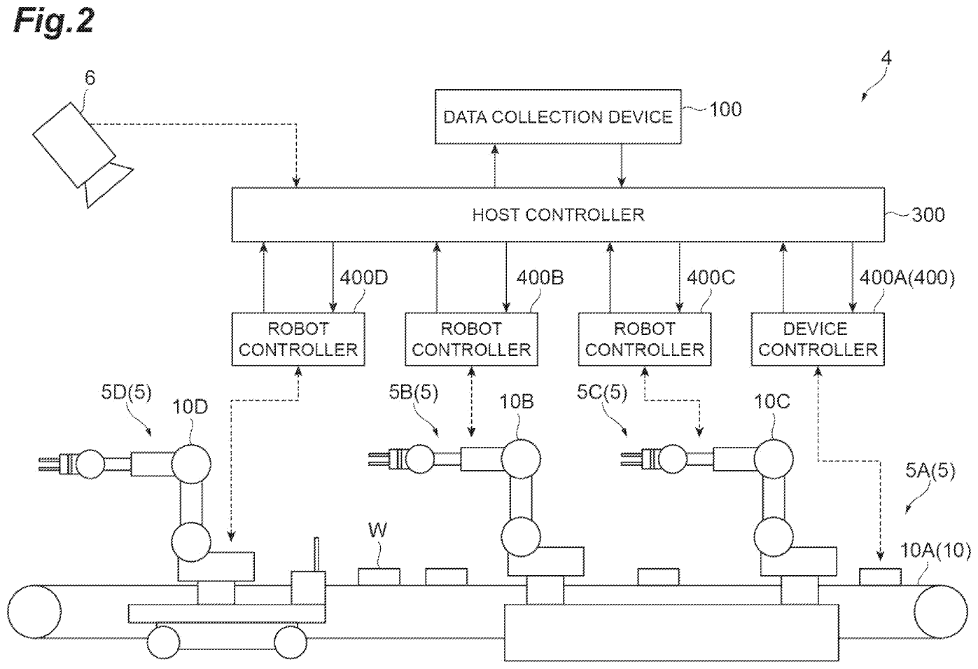

FIG. 2 is a schematic diagram illustrating the production device 4 that autonomously performs processing. The production device 4 illustrated in FIG. 2 includes a plurality of machines 5 including a robot and a process assignment unit 316 that collects state information of the real space. The robot autonomously performs at least a part of the processing based on the state information of the real space collected by the process assignment unit 316.

For example, the production device 4 includes the plurality of machines 5 and a host controller 300. Each of the plurality of machines 5 includes a machine body 10 and a local controller 400. The machine body 10 directly performs work on a workpiece W in the real space. Direct work is a work of applying some energy to the workpiece W, such as thermal, kinetic, or potential energy. The local controller 400 controls the machine body 10 to perform work.

Each of the plurality of machines 5 is, for example, an industrial machine. The plurality of machines 5 includes at least a robot (At least one machine 5 is a robot.). Further, the plurality of robots include an industrial machine that cooperates with the machine 5. Examples of the industrial machine cooperating with the robot include other robots, machine tools, and the like. The plurality of machines 5 illustrated in FIG. 2 include, but are not limited to, a transfer device 5A and robots 5B, 5C, 5D. The number and type of the machines 5 can be modified in any way, as long as the machine 5 includes at least one robot.

The transfer device 5A includes a device body 10A (machine body) and a device controller 400A (local controller). The device body 10A is driven by, for example, an electric motor or the like to convey the workpiece W. The device controller 400A controls the device body 10A to convey the workpiece W. Examples of the device body 10A include a belt conveyor, a roller conveyor, and a carousel.

The robot 5B includes a robot body 10B and a robot controller 400B. The robot 5C includes a robot body 10C and a robot controller 400C. The robot 5D includes a robot body 10D and a robot controller 400D. The robot bodies 10B, 10C, 10D (machine body) perform work on the workpiece W conveyed by the device body 10A. The robot controllers 400B, 400C, 400D (local controller) respectively control the robot bodies 10B, 10C, 10D to perform work. Examples of the work on the workpiece W include assembly of another workpiece W (for example, a sub-part) to the workpiece W carried by the device body 10A (for example, a base part), fastening (for example, bolt fastening) and joining (for example, welding) of parts in the workpiece W carried by the device body 10A, loading of the workpiece W to an NC machine tool installed around the device body 10A, unloading of the workpiece W from the NC machine tool, and the like.

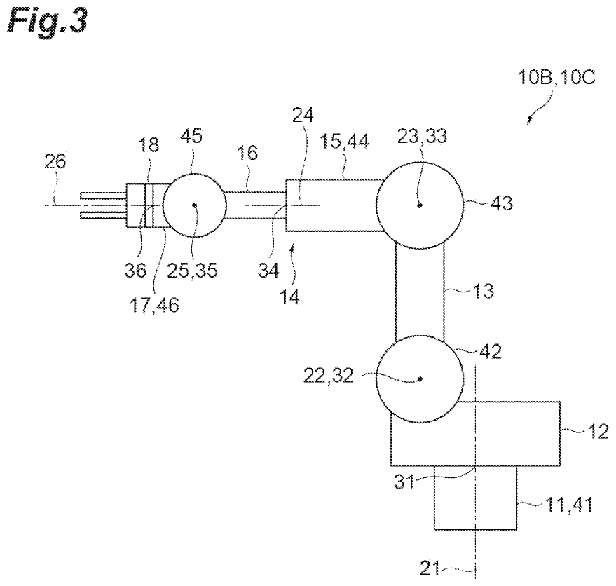

Robot bodies 10B, 10C are six-axis vertical articulated robots and include a base 11, a pivoting portion 12, a first arm 13, a second arm 14, a third arm 17, a tip portion 18, and actuators 41, 42, 43, 44, 45, 46 as illustrated in FIG. 3. The base 11 is placed around the device body 10A of the transfer device 5A. The pivoting portion 12 is mounted on the base 11 so as to pivot about a vertical axis 21. The first arm 13 is connected to the pivoting portion 12 so as to swing about an axis 22 that intersects (for example, is orthogonal to) the axis 21. Intersecting includes being skew such as so-called three-dimensional intersection. The second arm 14 is connected to a tip portion of the first arm 13 so as to swing about an axis 23 substantially parallel to the axis 22. The second arm 14 includes a swing portion 15 and a pivoting portion 16. The swing portion 15 is connected to the tip portion of the first arm 13 and extends along an axis 24 that intersects (for example, is orthogonal to) the axis 23. The pivoting portion 16 is connected to a tip portion of the swing portion 15 so as to pivot about the axis 24 and extends further along the axis 24. The third arm 17 is connected to a tip portion of the pivoting portion 16 so as to swing about an axis 25 that intersects (for example, is orthogonal to) the axis 24. The tip portion 18 is connected to a tip portion of the third arm 17 so as to pivot about an axis 26 that intersects (for example, is orthogonal to) the axis 25. Work tools, such as hands, suction nozzles, and weld torches, are attached to the tip portion 18.

As described above, the robot bodies 10B, 10C include a joint 31 connecting the base 11 and the pivoting portion 12, a joint 32 connecting the pivoting portion 12 and the first arm 13, a joint 33 connecting the first arm 13 and the second arm 14, a joint 34 connecting the swing portion 15 and the pivoting portion 16 in the second arm 14, a joint 35 portion connecting the pivoting portion 16 and the third arm 17, and a joint 36 connecting the third arm 17 and the tip portion 18.

The actuators 41, 42, 43, 44, 45, 46 include, for example, an electric motor and a reduction gear, and drive joints 31, 32, 33, 34, 35, 36, respectively. For example, the actuator 41 rotates the pivoting portion 12 around the axis 21. The actuator 42 swings the first arm 13 around the axis 22. The actuator 43 swings the second arm 14 around the axis 23. The actuator 44 rotates the pivoting portion 16 around the axis 24. The actuator 45 swings the third arm 17 around the axis 25. The actuator 46 rotates the tip portion 18 around the axis 26.

The configuration of the robot bodies 10B, 10C can be modified. For example, the robot bodies 10B, 10C may be a seven-axis redundant type robot in which one joint is further added to the six-axis vertical articulated robot, or may be a so-called SCARA type articulated robot.

Referring back to FIG. 2, the robot body 10D is a autonomous mobile robot. The robot body 10D is a robot similar to the robot bodies 10B, 10C in which the base 11 can be autonomous mobile. Examples of the autonomous mobile base 11 include electric automated guided vehicles (AGVs).

The host controller 300 performs wired or wireless synchronous communication with the local controllers 400 of the plurality of machines 5 to collect state information of the real space. Synchronous communication means that the plurality of machines 5 also perform communication with the local controller 400 for each cycle in synchronization with a synchronization frame of a certain cycle (the communication cycle). The local controller 400 controls the machine body 10 to autonomously perform at least a part of the processing based on the state information of the real space collected by the host controller 300.

The host controller 300 performs wired or wireless communication with the production instruction device 2 to acquire the production instruction. The communication between the host controller 300 and the production instruction device 2 may be synchronous communication or asynchronous communication. The host controller 300 may determine the processing to be performed by the plurality of machines 5 based on the production instruction. The host controller 300 may collect the state information of the real space including the state information of the plurality of machines 5 in the real space and the progress information of the processing, and autonomously select the process to be performed by each of the plurality of machines 5 based on the state information of the plurality of machines 5 and the progress information of the processing. The local controller 400 may autonomously perform the selected process based on the state information of the plurality of machines 5 in the real space and the progress information of the processing.

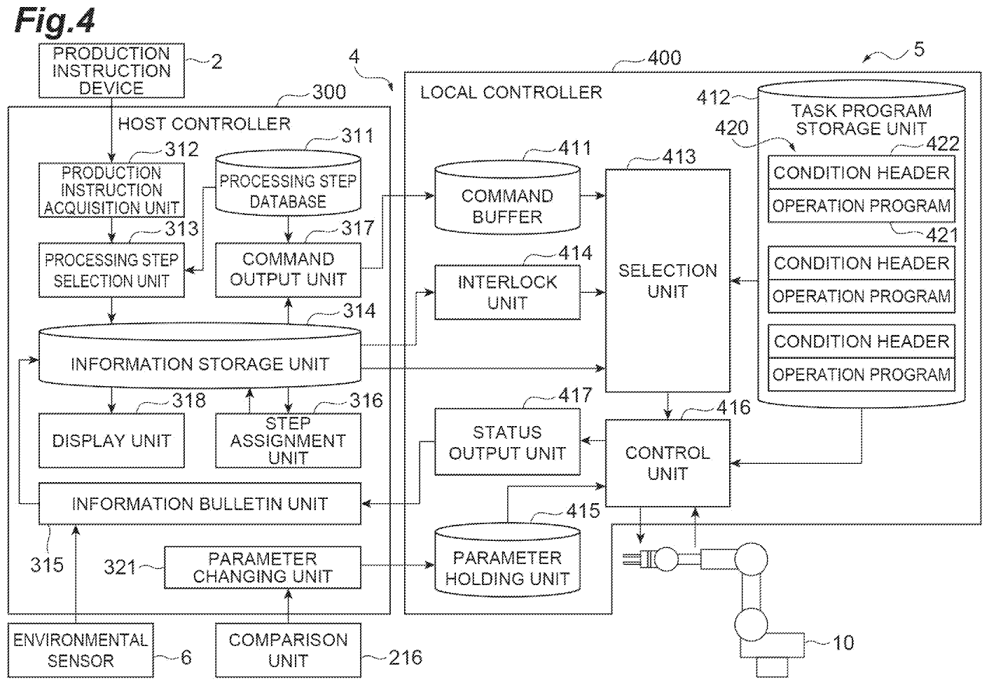

As illustrated in FIG. 4, the host controller 300 includes a processing database 311, a production instruction acquisition unit 312, a processing selection unit 313, an information storage unit 314, an information bulletin unit 315, the process assignment unit 316, and a command output unit 317 as functional blocks.

The processing database 311 stores a plurality of types of processing respectively corresponding to a plurality of types of products. Each of the plurality of types of processing includes a plurality of tasks (processes). The task is a unit of work performed by one machine 5. The plurality of tasks of one type of processing may include tasks to be performed by a plurality of machines 5 different from each other.

The production instruction acquisition unit 312 acquires the production instruction from the production instruction device 2. The production instruction includes the type of product and the production quantity for each type. The processing selection unit 313 selects a type of processing for each product based on the production instruction acquired by the production instruction acquisition unit 312 and a plurality of types of processing stored in the processing database 311. The processing selection unit 313 stores the selection result of the processing for each product in the information storage unit 314.

The information bulletin unit 315 collects state information in the real space and stores the state information in the information storage unit 314. The state information of the real space includes, for example, information regarding the plurality of machines 5 (hereinafter referred to as “machine information”) and information regarding the workpiece W (hereinafter referred to as “workpiece information”). Examples of the workpiece information include position/posture information of the workpiece W. Examples of the machine information include position/posture information of each of the plurality of machines 5. Examples of the position/posture information of the machine 5 include posture information of the robot bodies 10B, 10C and position/posture information of the robot body 10D. The posture information of the robot bodies 10B, 10C may be operation angle information of the joints 31, 32, 33, 34, 35, 36 or may be position/posture information of the tip portion 18. The position/posture information of the robot body 10D includes, for example, position/posture information of the base 11 and posture information of the robot body 10D with respect to the base 11.

The machine information includes information of a control signal generated between the local controller 400 and the machine body 10 (hereinafter referred to as “real control signal”). The real control signal may be an internal signal generated in the local controller 400 for controlling the machine body 10, a signal outputted from the local controller 400 to the machine body 10, or a feedback signal outputted from the machine body 10 to the local controller 400. Examples of the internal signal include command values of the position and posture of the machine body 10. Examples of the output signal include an output current value to the actuator of the machine body 10. Examples of the feedback signal include detection values of the position and posture, speed, force, and the like of the machine body 10 in the real space.

The information bulletin unit 315 updates the state information of the real space in accordance with the operation of the plurality of machines 5. For example, the information bulletin unit 315 acquires the status information of the machine body 10 in the real space from each of the plurality of local controllers 400, and updates the machine information based on the status information. The information bulletin unit 315 may further update the workpiece information based on the status information of the plurality of machines 5. For example, the information bulletin unit 315 may specify the work content performed on the workpiece W based on the status information of the plurality of machines 5, and may update the workpiece information based on the specified work content. The information bulletin unit 315 may update the environmental information further based on a detection result of an environmental sensor 6 provided separately from the plurality of machines 5.

The environmental sensor 6 detects a state of a work environment of the plurality of machines 5. Examples of the environmental sensor 6 include cameras that record a work environment of the plurality of machines 5. If the environmental sensor 6 is a camera, the information bulletin unit 315 performs image processing on the image recorded by the environmental sensor 6, and updates the state information of the real space further based on the image processing result. The environmental sensor 6 may be a sensor that detects the presence or absence of the workpiece W at a predetermined position with a laser beam or the like, or may be a sensor that detects the size or the like of the workpiece W. The production device 4 may include a plurality of environmental sensors 6.

The information bulletin unit 315 may further collect progress information of the processing (the processing stored by the information storage unit 314 for each product) and store the progress information in the information storage unit 314 in association with the processing. For example, the information bulletin unit 315 may collect the progress information of the processing based on the status state and store the progress information in the information storage unit 314. The progress information indicates, for example, whether each of a plurality of tasks included in the processing is unperformed, is being performed, or has been performed.

The progress information may include reservation information indicating which of the plurality of machines 5 is allocated to an unperformed task. The allocation of one of the plurality of machines 5 to the unperformed task may be performed by autonomous task selection of each of the plurality of machines 5 or may be performed by the host controller 300 (for example, the process assignment unit 316 described later).

The information bulletin unit 315 may be configured to prohibit allocation of another machine 5 to a task to which any of the plurality of machines 5 is allocated in the reservation information. For example, when allocation of another machine 5 is requested for a task to which one of the plurality of machines 5 is allocated in the reservation information, the information bulletin unit 315 may reject the request. In addition, the information bulletin unit 315 may exclude, in advance, a task to which one of the plurality of machines 5 is allocated from a target to which another machine 5 may be assigned.

The process assignment unit 316 assigns an unperformed task in the processing to one of the plurality of machines 5 based on the progress information. For example, the process assignment unit 316 assigns an unperformed task to one of the plurality of machines 5 with an algorithm for specifying a process to be performed by each of the plurality of machines 5 based on the type of process executable by each of the plurality of machines 5, machine information, and progress information. Thus, a task to be performed by each of the plurality of machines 5 is autonomously selected. The process assignment unit 316 updates the reservation information stored in the information storage unit 314 based on the result of the allocation.

The command output unit 317 outputs the execution command of the unperformed task to the local controller 400 based on the progress information of the processing. For example, the command output unit 317 specifies an unperformed task to be performed next for each product, and outputs an execution command of the specified task to the local controller 400 of the machine 5 allocated to the specified task by the reservation information.

When the information storage unit 314 stores a plurality of types of processing respectively corresponding to a plurality of products, the command output unit 317 may output the execution command of the task for each product based on the progress information of each of the plurality of types of processing. A plurality of execution commands respectively corresponding to the plurality of types of processing may be output to the same local controller 400. For example, in the information storage unit 314, if the first processing is assigned to a first product and the second processing is assigned to a second product, the execution command of the task in the first processing and the execution command of the task in the second processing may be output to the same local controller 400. The command output unit 317 may output the execution command of the task in response to a request from the local controller 400 in the synchronous communication, or may output the execution command regardless of the presence or absence of a request from the local controller 400.

The host controller 300 may further include a display unit 318. The display unit 318 causes a monitor to display information collected by the information bulletin unit 315 (information stored in the information storage unit 314). The monitor may be included in the host controller 300 itself, or may be included in another device (for example, the data collection device 100) capable of communicating with the host controller 300. For example, the display unit 318 may cause a display device of a user interface 195 (described below) of the data collection device 100 to display information collected by the information bulletin unit 315.

The local controller 400 includes a command buffer 411, a task program storage unit 412, a selection unit 413, a control unit 416, and a status output unit 417 as functional blocks. The command buffer 411 stores the execution command output by the command output unit 317 of the host controller 300. As described above, since a plurality of execution commands respectively corresponding to a plurality of types of processing can be output to the same local controller 400, a plurality of execution commands may be stored in the command buffer 411 at the same time.

The task program storage unit 412 stores two or more task programs 420 that respectively define operations in two or more tasks executable by the machine body 10. Each of the two or more task programs 420 includes an operation program 421 and a condition header 422. The operation program 421 represents the operation of the machine body 10. For example, the operation program 421 includes a plurality of operation commands arranged in time series so as to cause the machine body 10 to perform a group of operations. If the machine body 10 is one of the robot bodies 10B, 10C, 10D, the operation command in the operation program 421 includes a target position and a target posture of the tip portion 18, and a target displacement speed from the current position and the current posture to the target position and the target posture. The target position and the target posture of the tip portion 18 may be represented by target angles of the joints 31, 32, 33, 34, 35, 36, and the target displacement speed may be represented by target rotation speeds of the joints 31, 32, 33, 34, 35, 36. The condition header 422 represents an execution condition of the operation program 421. The execution condition is a condition for determining execution timing of the operation program 421 (operation timing of the machine body 10). The execution condition includes an execution propriety condition for determining whether the operation program 421 can be performed, and a priority of the operation program 421. The priority represents a priority order in the plurality of task programs 420 stored in the task program storage unit 412. If the priority is a numerical value representing the priority order itself, smaller value represents higher priority.

Examples of the execution propriety condition include the following.
Example 1) There is no obstacle to the operation of the machine body 10 within an operation range of the machine body 10.
Example 2) The workpiece W to be a target of a task (hereinafter simply referred to as “workpiece W”) is at a predetermined position.
Example 3) There is no other workpiece W at a loading destination of the workpiece W.
Example 4) The loading destination of the workpiece W is open.

Examples of the obstacle include another machine body 10, the workpiece W held by another machine body 10, and a human. Examples of the loading destination of the workpiece W include an NC machine tool which is an example of the other machine body 10. Examples of the loading destination being open include that a door of the NC machine tool is open.

The selection unit 413 selects one of the tasks corresponding to the execution command stored in the command buffer 411 (hereinafter referred to as a “corresponding task”) based on the execution condition (the condition header 422) of each of the plurality of tasks in the task program storage unit 412 and the state of the real space stored in the information storage unit 314. For example, the selection unit 413 checks whether each of the corresponding tasks can be performed. For example, the selection unit 413 checks whether the state information of the real space satisfies the execution propriety condition of each of one or more corresponding tasks. If two or more corresponding tasks are executable, the selection unit 413 selects one of the two or more executable corresponding tasks based on the priority. For example, the selection unit 413 selects the corresponding task with the highest priority.

The control unit 416 controls the machine body 10 to perform the corresponding task selected by the selection unit 413. The corresponding task corresponds to the execution command of the task autonomously selected by the process assignment unit 316 based on the state information and the progress information of the real space. The selection of the corresponding task by the selection unit 413 is autonomously performed based on the execution condition (the condition header 422) of each of the plurality of tasks in the task program storage unit 412 and the state of the real space in the information storage unit 314. Accordingly, executing the corresponding task selected by the selection unit 413 is an example of autonomously executing at least a part of the processing based on the state information of the real space and the progress information, and is also an example of autonomously executing the process assigned by the process assignment unit 316 based on the state information of the real space.

The execution command of the corresponding task is output to the local controller 400 of the machine 5 allocated to the corresponding task by the reservation information. Accordingly, executing the corresponding task selected by the selection unit 413 is also an example of executing the task assigned in the reservation information.

The control unit 416 may autonomously determine the first operation in the corresponding task with an algorithm for correcting the motion from the current position and current posture of the machine body 10 to the first target position and target posture of the corresponding task based on the state of the real space so as to avoid a collision with a surrounding object.

The status output unit 417 outputs the status information of the machine body 10 to the host controller 300. The status information includes at least position/posture information of the machine body 10. The status output unit 417 may output a task completion notification included in the status information in response to the completion of the execution of the task program 420. The status output unit 417 may output the status information in response to a request from the host controller 300 in the synchronous communication, or may output the status information regardless of the presence or absence of a request from the host controller 300.

If the machine body 10 is any of the robot bodies 10B, 10C, 10D, the local controller 400 may further include an interlock unit 414. Hereinafter, the machine body 10 controlled by the local controller 400 is referred to as “corresponding machine body 10”, and the machine body 10 controlled by the local controller 400 in another the machine 5 is referred to as “other machine body 10”.

The interlock unit 414 sets an entry prohibited area of the corresponding machine body 10 in the real space based on the progress of the task performed by the other machine body 10. For example, the interlock unit 414 sets the entry prohibited area of the corresponding machine body 10 based on the operation range when the other machine body 10 performs the task assigned in the reservation information. The interlock unit 414 may set the operation range itself when the other machine body 10 performs the task assigned in the reservation information as the entry prohibited area, or may set a range obtained by adding a predetermined margin to the operation range as the entry prohibited area.

If the local controller 400 includes the interlock unit 414, the execution propriety condition of the condition header 422 may further include that the entry restricted area set by the interlock unit 414 and the operation range of the corresponding machine body 10 do not overlap. The selection unit 413 selects a corresponding task in which the entry restricted area does not overlap the operation range of the corresponding machine body 10.

The local controller 400 may further include a parameter holding unit 415. The parameter holding unit 415 stores one or more control parameters for controlling the machine body 10. Examples of the one or more control parameters include a position control gain, a speed control gain, and a current control gain. If the local controller 400 includes the parameter holding unit 415, the control unit 416 controls the machine body 10 based on one or more control parameters stored in the parameter holding unit 415.

### Virtual Production Device

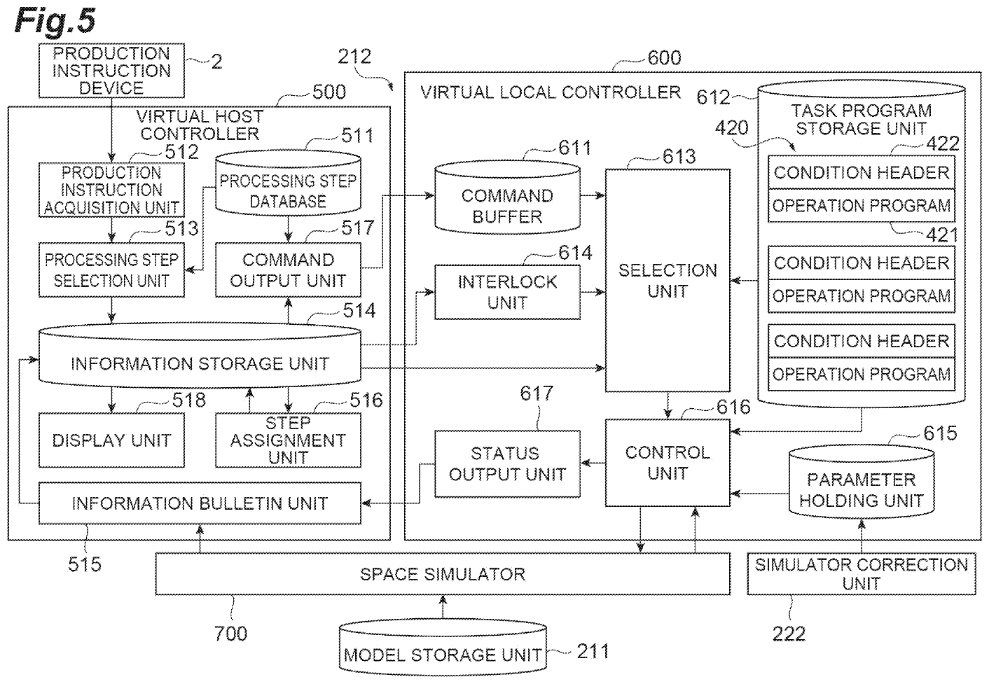

FIG. 5 is a schematic diagram illustrating the virtual production device 212 that autonomously performs a virtual processing. The virtual production device 212 illustrated in FIG. 5 includes a plurality of virtual machines 600 including a virtual robot corresponding to the robot and a process assignment unit 516 that collects state information of the virtual space. The virtual robot autonomously performs at least a part of the virtual processing based on the state information of the virtual space collected by the process assignment unit 516.

For example, the virtual production device 212 includes a virtual host controller 500, the plurality of virtual machines 600, and a space simulator 700. The virtual host controller 500 corresponds to the host controller 300. The plurality of virtual machines 600 respectively correspond to the plurality of machines 5. Each of the plurality of virtual machines 600 is configured similarly to the local controller 400.

The space simulator 700 calculates the numerical data representing the state of the machine body 10 after the operation without operating the machine body 10 in the real space based on the processing performed by each of the plurality of virtual machines 600 similarly to the local controller 400. Calculating, by the space simulator 700, the numerical data representing the state of the machine body 10 after the operation based on the processing of each of the plurality of virtual machines 600 is an example of operating the machine body 10 in the virtual space (simulating the operation of the machine body 10 in the virtual space).

The virtual host controller 500 is configured similarly to the host controller 300, and includes a task database 511, a production instruction acquisition unit 512, a processing selection unit 513, an information storage unit 514, a virtual information bulletin unit 515, the process assignment unit 516, and a command output unit 517 as functional blocks. The task database 511 stores a plurality of types of processing respectively corresponding to a plurality of types of products. The production instruction acquisition unit 512 acquires a production instruction from the production instruction device 2. The processing selection unit 513 selects a type of processing for each product based on the production instruction acquired by the production instruction acquisition unit 512 and a plurality of types of processing stored in the task database 511, and stores the selected processing in the information storage unit 514.

The virtual information bulletin unit 515 collects state information of the virtual space and stores the state information in the information storage unit 514. Similarly to the state information of the real space, the state information of the virtual space includes, for example, information about the plurality of virtual machines 600 (hereinafter referred to as “virtual machine information”) and information about a virtual workpiece (hereinafter referred to as “virtual workpiece information”). Examples of the virtual workpiece information include position/posture information of the virtual workpiece in the virtual space. Examples of the virtual machine information include position/posture information of the plurality of virtual machines 600 in the virtual space.

The virtual machine information includes information of control signals generated between the plurality of virtual machines 600 and the space simulator 700 (hereinafter, referred to as “virtual control signal”). The virtual control signal may be an internal signal generated in the virtual machine 600 for controlling the machine body 10 or may be a feedback signal output from the space simulator 700 to the virtual machine 600. Examples of the internal signal include command values of the position and posture of the machine body 10. Examples of the feedback signal include calculation results of the position, posture, speed, force, and the like of the machine body 10 in the virtual space.

The virtual information bulletin unit 515 updates the state information of the virtual space in accordance with the operation of the plurality of virtual machines 600. For example, the virtual information bulletin unit 515 acquires the status information of the machine body 10 in the virtual space from each of the plurality of virtual machines 600, and updates the virtual machine information based on the status information. The virtual information bulletin unit 515 may further update the virtual workpiece information based on the status information of the plurality of virtual machines 600. For example, the virtual information bulletin unit 515 may specify the work content performed on the virtual workpiece based on the status information of the plurality of virtual machines 600, and may update the virtual workpiece information based on the specified work content.

The virtual information bulletin unit 515 may further collect progress information of a virtual processing (a virtual processing stored by the information storage unit 514 for each product) and store the progress information in the information storage unit 514 in association with the virtual processing. For example, the virtual information bulletin unit 515 may collect the progress information of the virtual processing based on the status state and store the progress information in the information storage unit 514. The progress information indicates, for example, whether each of a plurality of tasks included in the virtual processing is unperformed, is being performed, or has been performed.

Similarly to the progress information of the processing, the progress information of the virtual processing may include reservation information indicating which of the plurality of virtual machines 600 is allocated to an unperformed task. Allocating one of the plurality of virtual machines 600 to the unperformed task may be performed by autonomous task selection of each of the plurality of virtual machines 600 or may be performed by the virtual host controller 500 (for example, the process assignment unit 516 described later).

The virtual information bulletin unit 515 may be configured to prohibit allocating another virtual machine 600 to a task to which any of the plurality of virtual machines 600 is assigned in the reservation information. For example, when allocation of another virtual machine 600 is requested for a task to which any of the plurality of virtual machines 600 is allocated in the reservation information, the virtual information bulletin unit 515 may reject the request. In addition, the virtual information bulletin unit 515 may exclude a task to which any one of the plurality of virtual machines 600 is allocated from a target to which another virtual machine 600 may be allocated in advance.

The process assignment unit 516 assigns an unperformed task in the virtual processing to one of the plurality of virtual machines 600 based on the progress information of the virtual processing. For example, the process assignment unit 516 assigns an unperformed task to any of the plurality of virtual machines 600 with an algorithm for specifying a process to be performed by each of the plurality of virtual machines 600 based on the type of process executable by each of the plurality of the virtual machines 600, the virtual machine information, and the progress information of the virtual processing. Thus, a task to be performed by each of the plurality of virtual machines 600 is autonomously selected. The process assignment unit 516 updates the reservation information stored in the information storage unit 514 based on the result of the assignment.

The command output unit 517 outputs the execution command of the unperformed task to the virtual machine 600 based on the progress information of the virtual processing. For example, the command output unit 517 specifies an unperformed task to be performed next for each product, and outputs an execution command of the specified task to the virtual machine 600 allocated to the specified task by the reservation information.

The virtual host controller 500 may further include a display unit 518. The display unit 518 causes a monitor to display information collected by the virtual information bulletin unit 515 (information stored in the information storage unit 514). The monitor may be included in the cell simulator 200 itself including the virtual host controller 500, or may be included in another device capable of communicating with the cell simulator 200. For example, the display unit 518 may cause a display device of a user interface 295 (described below) of the cell simulator 200 to display information collected by the virtual information bulletin unit 515.

The virtual machine 600 includes a command buffer 611, a task program storage unit 612, a selection unit 613, a control unit 616, and a status output unit 617 as functional blocks. The command buffer 611 stores the execution command output by the command output unit 517 of the virtual host controller 500. The task program storage unit 612 stores two or more task programs 420, similarly to the task program storage unit 412.

The selection unit 613 selects one of the tasks corresponding to the execution command stored in the command buffer 611 (hereinafter referred to as “corresponding tasks”) based on the execution condition (the condition header 422) of each of the plurality of tasks in the task program storage unit 612 and the state of the virtual space stored in the information storage unit 514. For example, the selection unit 613 checks whether each of the corresponding tasks can be performed. For example, the selection unit 613 checks whether the state information of the virtual space satisfies the execution propriety condition of each of one or more corresponding tasks. If two or more corresponding tasks are executable, the selection unit 613 selects one of the two or more executable corresponding tasks based on the priority. For example, the selection unit 613 selects the corresponding task with the highest priority.

The control unit 616 outputs, to the space simulator 700, a control signal for controlling the machine body 10 to perform the corresponding task selected by the selection unit 613. The space simulator 700 causes the machine body 10 to perform the corresponding task in the virtual space based on the control signal and the model stored in the model storage unit 211. For example, the space simulator 700 calculates the transition of the position and posture of the machine body 10 during the execution of the corresponding task without actually operating the machine body 10.

The status output unit 617 outputs the status information of the machine body 10 in the virtual space to the virtual host controller 500. The status information includes at least position/posture information of the machine body 10 in the virtual space. The status output unit 617 may output a task completion notification included in the status information in response to the completion of the execution of the task program 420.

Similarly to the local controller 400, the virtual machine 600 may further include an interlock unit 614. Similarly to the interlock unit 414, the interlock unit 614 sets the entry prohibited area of the corresponding machine body 10 in the virtual space based on the progress of the task performed by another machine body 10. If the virtual machine 600 includes the interlock unit 614, the selection unit 613 selects a corresponding task in which the entry restricted area and the operation range of the corresponding machine body 10 do not overlap.

The virtual machine 600 may further include a parameter holding unit 615. The parameter holding unit 615 stores one or more simulation parameters for operating the machine body 10 in the virtual space. Examples of the one or more simulation parameters include a position control gain, a speed control gain, a current control gain, and the like. If the operation of the machine body 10 is opening and closing of a door or the like, the parameter holding unit 615 may store a standby time from the output of the control signal to the completion of the operation of the machine body 10 as a simulation parameter. If the virtual machine 600 includes the parameter holding unit 615, the control unit 616 controls the machine body 10 based on one or more control parameters stored in the parameter holding unit 615.

As described above, according to a system in which the production device 4 autonomously determines how to assign processing corresponding to a production instruction from the host controller 300 to the plurality of machines 5 and at what timing the plurality of machines 5 are caused to perform the assigned processing, and which autonomously operates based on the determination result, the production system 1 can be flexibly operated. Even under such flexible operation, by executing the virtual processing with the same algorithm as the algorithm of the production device 4 based on the same production instruction as the production instruction for the production device 4, a more reliable comparison reference can be generated, and the autonomous operation of the production device 4 can be verified in real time.

If the selection of the task to be performed by each of the plurality of machines 5 is autonomously performed, the deviation between the transition timing of the state of the real space based on the start time of the processing and the transition timing of the state of the virtual space based on the start time of the virtual processing, and the difference between the task performed by each of the plurality of machines 5 and the task performed by each of the plurality of virtual machines 600 may occur. Accordingly, the comparison unit 216 may further compare the task performed by each of the plurality of machines 5 with the task performed by each of the plurality of virtual machines 600.

### Modification of Simulator

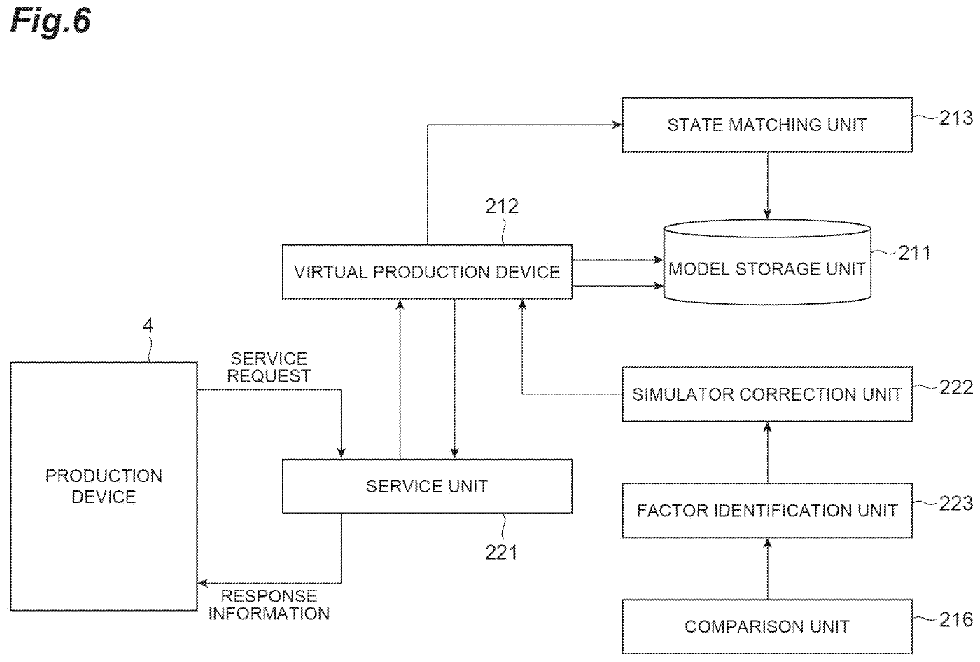

As illustrated in FIG. 6, the cell simulator 200 may further include a service unit 221. The service unit 221 causes the virtual production device 212 to perform on-demand simulation in response to a request from the production device 4, and returns response information based on a result of the on-demand simulation to the production device 4. The on-demand simulation is a simulation specified by a request from the production device 4. Examples of the on-demand simulation include a simulation for generating a recovery operation for resuming a stopped operation when the production device 4 is abnormally stopped.

For example, in response to a request from the production device 4, the service unit 221 matches the state of the virtual space with the state of the real space, and temporarily generates a recovery operation. Thereafter, the service unit 221 repeats causing the virtual production device 212 to perform the recovery operation in the virtual space and correcting the recovery operation based on the result of the recovery operation in the virtual space until the result of the recovery operation satisfies a predetermined condition, thereby generating the recovery operation, and returns the generated recovery operation to the production device 4 as response information. Examples of the predetermined condition include a condition that no collision between objects occurs due to the recovery operation.

As another example of the on-demand simulation, there is a simulation for correcting the corresponding task so as to satisfy the execution propriety condition if the corresponding task does not satisfy the execution propriety condition.

According to the simulator that causes the virtual production device 212 to perform the virtual processing based on the production instruction for the production device 4, the state of the virtual cell transitions together with the state of the cell. Accordingly, the on-demand simulation corresponding to the request from the production device can be quickly performed based on the state of the virtual cell transitioned together with the state of the cell, and the response information can be returned to the production device in a short standby time.

The cell simulator 200 may further include a simulator correction unit 222. The simulator correction unit 222 changes the simulation parameter for causing the virtual production device 212 to perform the virtual processing so that the deviation between the execution result of the processing and the execution result of the virtual processing decreases based on the comparison result by the comparison unit 216. For example, if the standby time from the output of the control signal to the completion of the operation of the machine body 10 is stored as the simulation parameter as described above, and if the deviation between the execution result of the processing and the execution result of the virtual processing occurs due to the stored standby time, the simulator correction unit 222 changes the standby time so as to reduce the deviation.

The cell simulator 200 may further include a factor identification unit 223. If the comparison result by the comparison unit 216 includes a deviation between at least a part of the execution result of the processing by the robot and at least a part of the execution result of the virtual processing by the virtual robot, a virtual machine other than the robot that is a factor of the deviation is specified. If the virtual machine that is the factor of the deviation is specified by the factor identification unit 223, the simulator correction unit 222 corrects the simulation parameter for causing the virtual machine that is the factor of the deviation to perform at least a part of the virtual processing.

For example, in a case where the execution start time of the task by the robot and the start time of the task by the virtual robot deviate from each other due to the difference in the standby time for opening and closing the door in the machine tool, the factor identification unit 223 specifies the machine tool as the virtual machine that is the factor of the deviation. The simulator correction unit 222 corrects the standby time for door opening and closing stored as the simulation parameter of the machine tool that is the factor of the deviation.

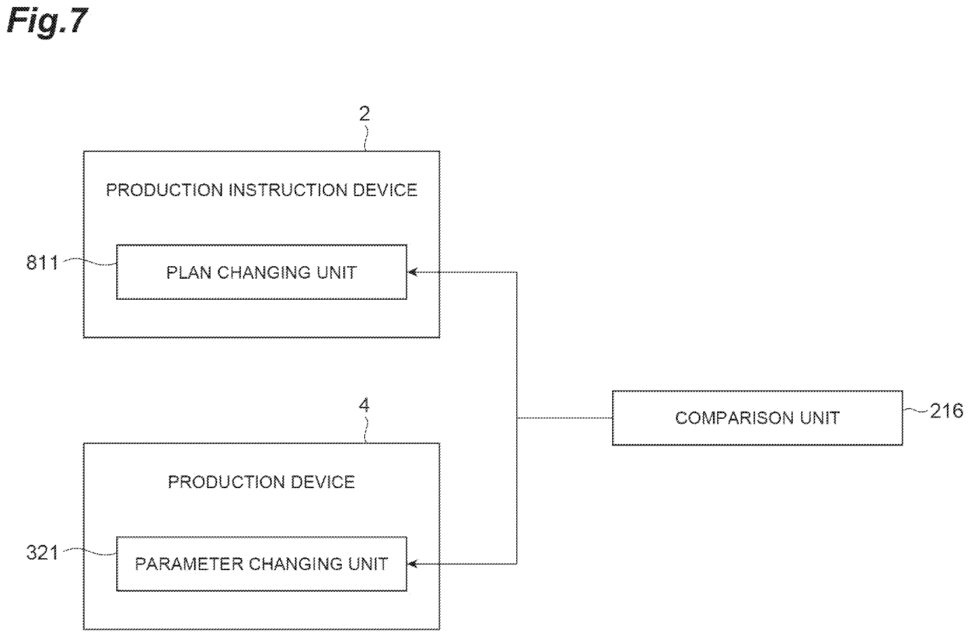

As illustrated in FIG. 7, the host controller 300 may further include a parameter changing unit 321. Based on the comparison result by the comparison unit 216, the parameter changing unit 321 changes the control parameter for causing the production device 4 to perform the processing so as to reduce the deviation between the execution result of the processing and the execution result of the virtual processing. For example, the parameter changing unit 321 changes the control parameter in the parameter holding unit 415 so that the deviation between the execution result of the processing and the execution result of the virtual processing is reduced (see FIG. 4). The parameter changing unit 321 may be included in the host controller 300 or the local controller 400.

The production instruction device 2 may further include a plan changing unit 811. The plan changing unit 811 changes the production plan based on the comparison result by the comparison unit 216. For example, when the deviation between the execution result of the processing and the execution result of the virtual processing exceeds a predetermined level in one cell 3, the plan changing unit 811 changes the production plan so that the production plan assigned to the cell 3 is performed in another cell 3.

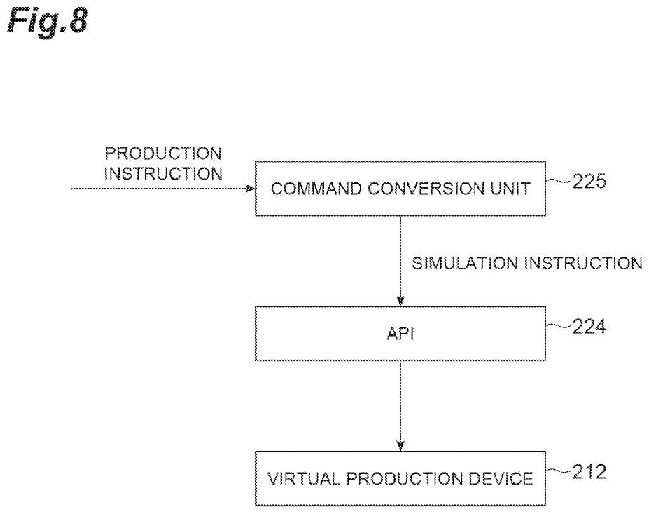

As illustrated in FIG. 8, the cell simulator 200 may further include an API 224 and a command conversion unit 225. The API 224 is an application programming interface (API) that operates the virtual production device based on a simulation instruction. The command conversion unit 225 receives the production instruction, converts it into a simulation instruction, and passes it to the API 224. The cell simulator 200 that causes the virtual production device 212 to perform the virtual processing based on the same production instruction as the production instruction for the production device 4 may readily be constructed by utilizing a simulator that operates based on an instruction in a format different from the production instruction.

### Hardware Configuration

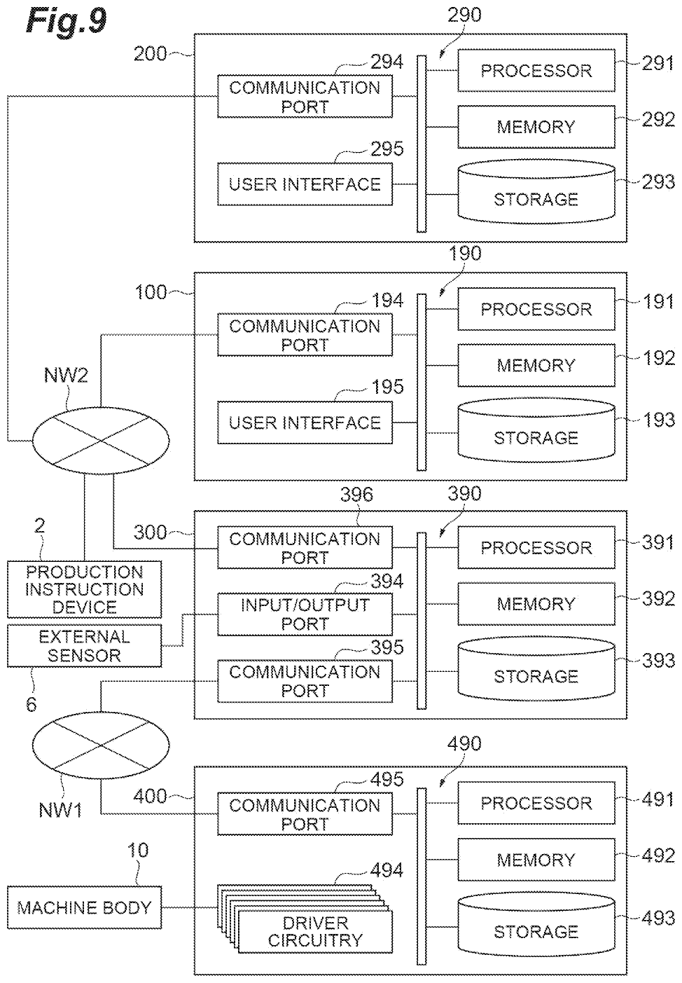

FIG. 9 is a block diagram illustrating a hardware configuration of the data collection device 100, the cell simulator 200, the host controller 300, and the local controller 400. As illustrated in FIG. 9, the local controller 400 includes circuitry 490. The circuitry 490 includes a processor 491, a memory 492, storage 493, driver circuitry 494, and a communication port 495. The storage 493 is composed of one or more non-volatile memory devices, such as flash memory or a hard disk. The storage 493 stores a program for configuring the above-described functional blocks in the local controller 400.

The memory 492 is composed of one or more volatile memory devices, such as random-access memory. The memory 492 temporarily stores the program loaded from the storage 493. The processor 491 is composed of one or more computing devices such as central processing units (CPUs) or graphics processing units (GPUs). The processor 491 causes the local controller 400 to configure each functional block described above by executing the program loaded in the memory 492. The calculation result by the processor 491 is temporarily stored in the memory 492.

The driver circuitry 494 operates the machine body 10 in response to a request from the processor 491. The communication port 495 communicates with the host controller 300 via a communication network NW1 for control in response to a request from the processor 491.

The host controller 300 includes circuitry 390. The circuitry 390 includes a processor 391, a memory 392, storage 393, an input/output port 394, a communication port 395, and a communication port 396. The storage 393 is composed of one or more non-volatile memory devices, such as flash memory or a hard disk. The storage 393 stores a program for configuring the above-described functional blocks in the host controller 300.

The memory 392 is composed of one or more volatile memory devices, such as random-access memory. The memory 392 temporarily stores the program loaded from the storage 393. The processor 391 is composed of one or more computing devices such as CPUs or GPUs. The processor 391 causes the host controller 300 to configure each functional block described above by executing the program loaded in the memory 392. The calculation result by the processor 391 is temporarily stored in the memory 392.

The input/output port 394 exchanges information with the environmental sensor 6 in response to a request from the processor 391. The communication port 395 communicates with the local controller 400 via the communication network NW1 in response to a request from the processor 391. The communication port 396 communicates with the data collection device 100, the cell simulator 200, and the production instruction device 2 via a communication network NW2 in response to requests from the processor 391. The communication network NW2 may be a network different from the communication network NW1 or may be the same network as the communication network NW1.

The data collection device 100 includes circuitry 190. The circuitry 190 includes a processor 191, a memory 192, storage 193, a communication port 194, and the user interface 195. The storage 193 is composed of one or more non-volatile memory devices, such as flash memory or a hard disk. The storage 193 stores a program for configuring the above-described functional blocks in the data collection device 100.

The memory 192 is composed of one or more volatile memory devices, such as random-access memory. The memory 192 temporarily stores the program loaded from the storage 193. The processor 191 is composed of one or more computing devices such as CPUs or GPUs. The processor 191 causes the data collection device 100 to configure each functional block described above by executing the program loaded in the memory 192. The calculation result by the processor 191 is temporarily stored in the memory 192.

The communication port 194 communicates with the cell simulator 200 and the host controller 300 via the communication network NW2 in response to requests from the processor 191. The user interface 195 inputs and outputs information to and from the operator in response to a request from the processor 191. For example, the user interface 195 includes a display device such as a liquid crystal monitor or an organic electro-luminescence (EL) monitor, and an input device such as a keyboard or a mouse. The input device may be integrated with the display device as a touch panel.

The cell simulator 200 includes circuitry 290. The circuitry 290 includes a processor 291, a memory 292, storage 293, a communication port 294, and the user interface 295. The storage 293 is composed of one or more non-volatile memory devices, such as flash memory or a hard disk. The storage 293 stores a program for configuring the above-described functional blocks in the cell simulator 200.

The memory 292 is composed of one or more volatile memory devices, such as random-access memory. The memory 292 temporarily stores the program loaded from the storage 293. The processor 291 is composed of one or more computing devices such as CPUs or GPUs. The processor 291 causes the cell simulator 200 to configure each functional block described above by executing the program loaded in the memory 292. The calculation result by the processor 291 is temporarily stored in the memory 292.

The communication port 294 communicates with the data collection device 100, the host controller 300, and the production instruction device 2 via the communication network NW2 in response to requests from the processor 291. The user interface 295 inputs and outputs information to and from the operator in response to a request from the processor 291. For example, the user interface 295 includes a display device such as a liquid crystal monitor or an organic electro-luminescence (EL) monitor, and an input device such as a keyboard or a mouse. The input device may be integrated with the display device as a touch panel.

The above-described hardware configuration is merely an example, and can be modified. For example, the cell simulator 200 may be incorporated into the data collection device 100. The cell simulator 200 and the data collection device 100 may be incorporated into the host controller 300.

### Production Procedure

As an example of the production method, an execution procedure of processing and virtual processing by the production system 1 will be described. This procedure includes: executing the processing on a workpiece in a real space based on a production instruction transmitted based on a production plan to produce a product; causing a virtual production device to perform the virtual processing corresponding to the processing performed by the production device in a virtual space based on the production instruction; and comparing an execution result of the processing with an execution result of the virtual processing.

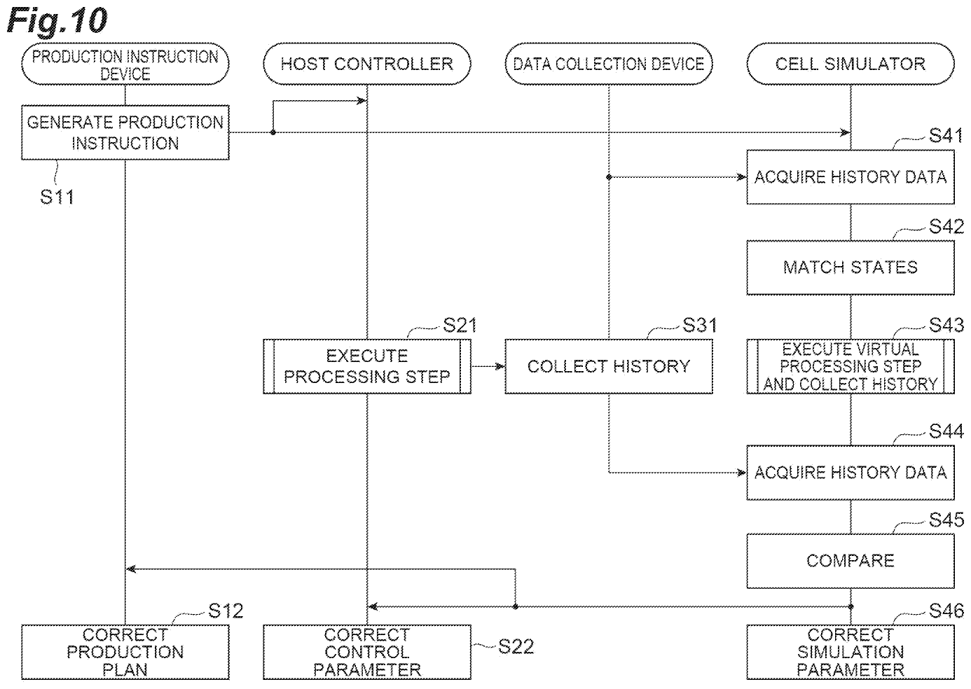

For example, as illustrated in FIG. 10, the production instruction device 2 executes an operation S11. In the operation S11, the production instruction device 2 transmits a production instruction based on a cell-based production plan to the host controller 300 and the cell simulator 200.

In response to receiving the production instruction sent from the production instruction device 2, the host controller 300 executes the processing in an operation S21. The data collection device 100 executes an operation S31 in parallel with the execution of the processing by the host controller 300. In the operation S31, the history acquisition unit 111 collects the execution history of the processing and stores the execution history in the database 112.

In response to receiving the production instruction sent from the production instruction device 2, the cell simulator 200 executes operations S41, S42. In the operation S41, the state matching unit 213 acquires state information of the real space from the database 112. In the operation S42, the state matching unit 213 matches the state of the virtual space with the state of the real space based on the information acquired in the operation S41.

The cell simulator 200 then executes an operation S43. In the operation S43, the virtual production device 212 performs the virtual processing in the virtual space. In the operation S43, in parallel with the execution of the virtual processing, the virtual data collection unit 214 collects the execution history of the virtual processing and stores the execution history in the virtual database 215.

The cell simulator 200 then executes operations S44, S45. In the operation S44, the comparison unit 216 acquires, from the database 112, the execution history of the processing collected by the history acquisition unit 111 in the operation S31 as the execution result of the processing. In the operation S45, the comparison unit 216 compares the execution result of the processing with the execution result of the virtual processing. For example, the comparison unit 216 compares the execution history of the processing acquired in the operation S44 with the execution history of the virtual processing collected by the virtual data collection unit 214 at the operation S43 and stored in the virtual database 215. In the operation S45, the abnormality detection unit 217 may detect an abnormality in the production device 4 based on the comparison result by the comparison unit 216.

Based on the comparison result by the comparison unit 216, the cell simulator 200 may further execute an operation S46. In the operation S46, the simulator correction unit 222 changes the simulation parameter for causing the virtual production device 212 to perform the virtual processing so as to reduce the deviation between the execution result of the processing and the execution result of the virtual processing.

Based on the comparison result by the comparison unit 216, the host controller 300 may further execute an operation S22. In the operation S22, the parameter changing unit 321 changes the control parameter for causing the production device 4 to perform the processing so as to reduce the deviation between the execution result of the processing and the execution result of the virtual processing.

Based on the comparison result by the comparison unit 216, the production instruction device 2 may further execute an operation S12. In the operation S12, the plan changing unit 811 changes the production plan based on the comparison result by the comparison unit 216.

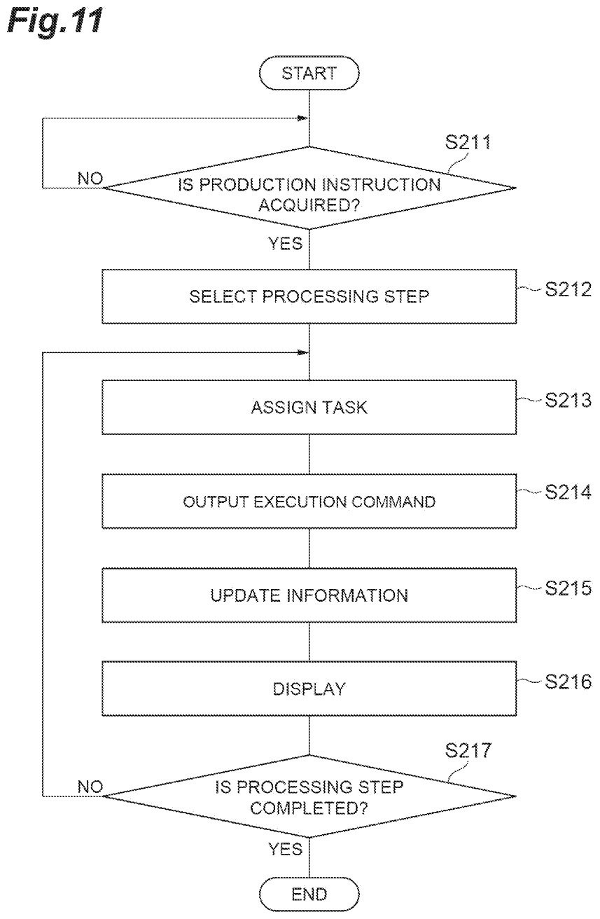

FIG. 11 is a flowchart illustrating a procedure executed by the host controller 300 in the processing. As illustrated in FIG. 11, the host controller 300 first executes operations S211, S212. In the operation S211, the production instruction acquisition unit 312 waits for the acquisition of a production instruction. In the operation S212, the processing selection unit 313 selects processing for each product based on the production instruction acquired by the production instruction acquisition unit 312 and a plurality of types of processing stored in the processing database 311.

The host controller 300 then performs operations S213, S214. In the operation S213, the process assignment unit 316 assigns an unperformed task in the processing to one of the plurality of machines 5 based on the progress information of the processing. In the operation S214, the command output unit 317 outputs the execution command of the unperformed task to the local controller 400 based on the progress information of the processing.

The host controller 300 then executes operations S215, S216. In the operation S215, the information bulletin unit 315 collects state information of the real space and progress information of the processing and stores the collected information in the information storage unit 314. In the operation S216, the display unit 318 causes the monitor to display information stored in the information storage unit 314.

The host controller 300 then executes an operation S217. In the operation S217, the command output unit 317 checks whether the processing selected by the processing selection unit 313 for each product is completed. If it is determined in the operation S217 that at least a part of the processing has not been performed, the host controller 300 returns the processing to the operation S213. Thereafter, until the processing for each product is completed, the output of the execution command and the update of the information are repeated. If it is determined in the operation S217 that the processing is completed, the host controller 300 ends the processing.

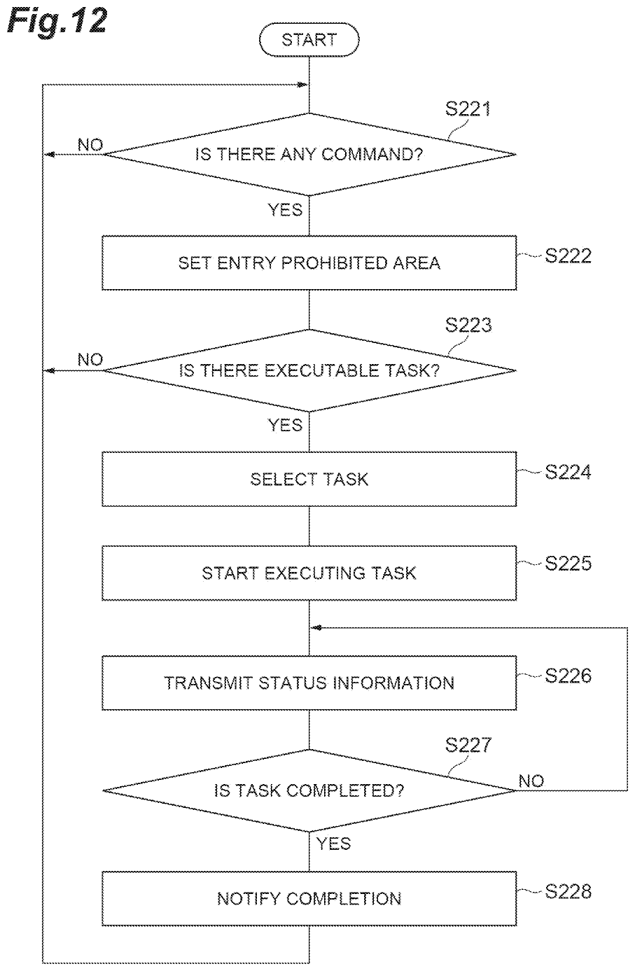

FIG. 12 is a flowchart illustrating a procedure executed by the local controller 400 in the processing. As illustrated in FIG. 12, the local controller 400 first executes an operation S221. In the operation S221, the selection unit 413 waits for the execution command to be stored in the command buffer 411.

The local controller 400 then executes operations S222, S223. In the operation S222, the interlock unit 414 sets the entry prohibited area of the corresponding machine body 10 in the real space based on the progress of the task performed by the other machine body 10. In the operation S223, based on the execution condition (the condition header 422) of each of the plurality of tasks in the task program storage unit 412 and the state of the real space stored in the information storage unit 314, the selection unit 413 checks whether any of the tasks (the corresponding tasks) corresponding to the execution command stored in the command buffer 411 is executable. If it is determined in the operation S223 that there is no executable corresponding task, the local controller 400 returns the processing to the operation S221.

If it is determined in the operation S223 that there is a corresponding task that is executable, the local controller 400 executes an operation S224. In the operation S224, the selection unit 413 selects a corresponding task that is executable. If two or more corresponding tasks are executable, the selection unit 413 selects the corresponding task with the highest priority.

The local controller 400 then executes operations S225, S226. In the operation S225, the control unit 416 starts to control the machine body 10 so as to perform the corresponding task selected by the selection unit 413. In the operation S226, the status output unit 417 transmits the status information of the machine body 10 to the host controller 300.

The local controller 400 then executes an operation S227. In the operation S227, the status output unit 417 checks whether the execution of the corresponding task is completed. If it is determined that the execution of the corresponding task is not completed, the local controller 400 returns the processing to the operation S226. Thereafter, transmission of the status information of the machine body 10 to the host controller 300 is repeated until the execution of the corresponding task is completed.

If it is determined in the operation S227 that the execution of the corresponding task is completed, the status output unit 417 executes an operation S228. In the operation S228, the status output unit 417 includes a completion notification of the corresponding task in status information and transmits the status information to the host controller 300. The local controller 400 then returns the processing to the operation S221. The local controller 400 repeatedly executes the above processing at a predetermined control cycle.

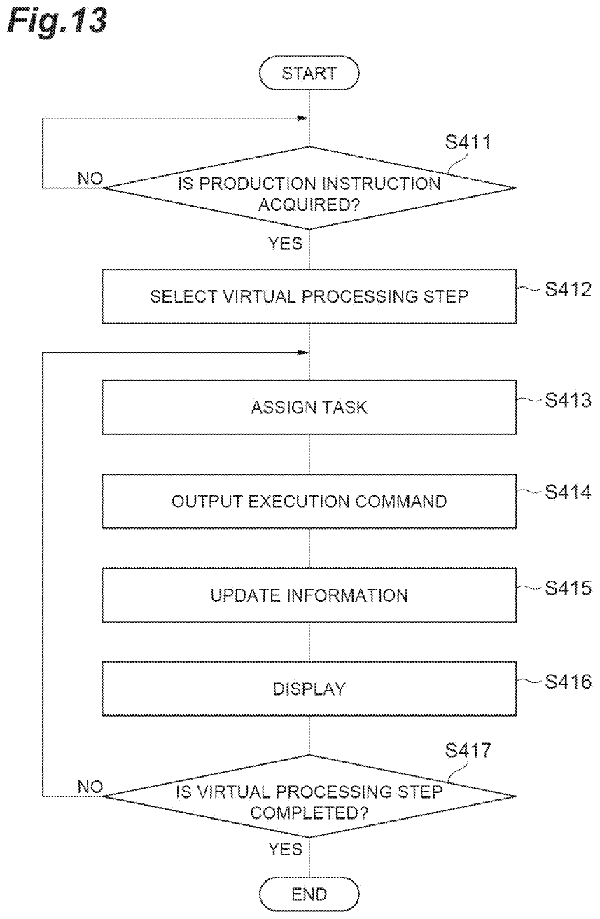

FIG. 13 is a flowchart illustrating a procedure executed by the virtual host controller 500 in the virtual processing. As illustrated in FIG. 13, the virtual host controller 500 first executes operations S411, S412. In the operation S411, the production instruction acquisition unit 512 waits for the acquisition of the production instruction. In the operation S412, the processing selection unit 513 selects a virtual processing for each product based on the production instruction acquired by the production instruction acquisition unit 512 and the plurality of types of processing stored in the task database 511.

The virtual host controller 500 then executes operations S413, S414. In the operation S413, the process assignment unit 516 assigns an unperformed task in the processing to one of the plurality of virtual machines 600 based on the progress information of the processing. In the operation S414, the command output unit 517 outputs the execution command of the unperformed task to the virtual machine 600 based on the progress information of the processing.

The virtual host controller 500 then executes operations S415, S416. In the operation S415, the virtual information bulletin unit 515 collects state information of the virtual space and progress information of the virtual processing and stores the information in the information storage unit 514. In the operation S416, the display unit 518 causes the monitor to display information stored in the information storage unit 514.

The virtual host controller 500 then executes an operation S417. In the operation S417, the command output unit 517 checks whether the virtual processing selected by the processing selection unit 513 for each product is completed. If it is determined in the operation S417 that at least a part of the virtual processing has not been performed, the virtual host controller 500 returns the processing to the operation S413. Thereafter, the output of the execution command and the update of the information are repeated until the virtual processing for each product is completed. If it is determined in the operation S417 that the virtual processing is completed, the virtual host controller 500 ends the processing.

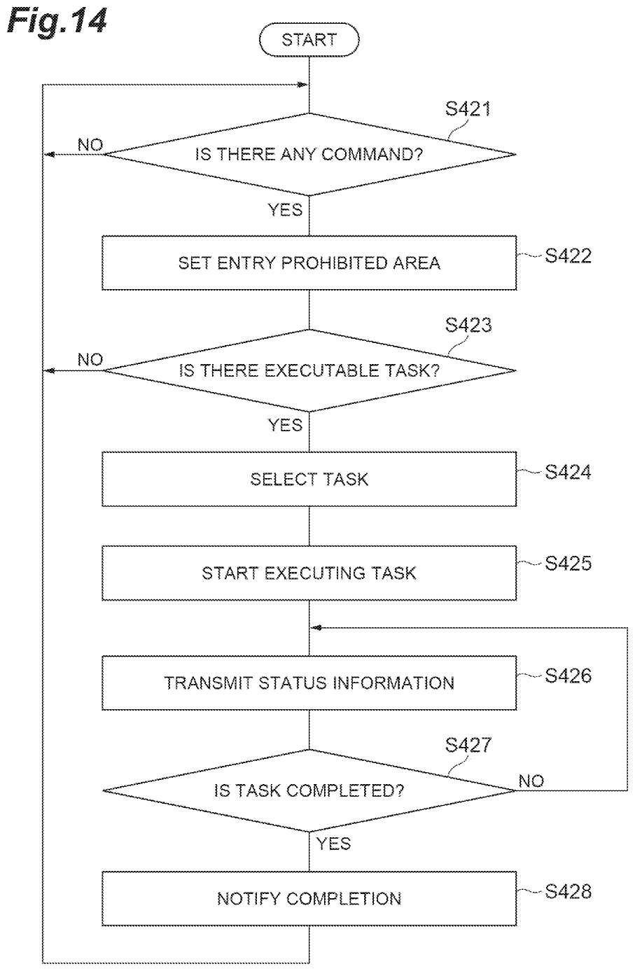

FIG. 14 is a flowchart illustrating a procedure executed by the virtual machine 600 in the virtual processing. As illustrated in FIG. 14, the virtual machine 600 first executes an operation S421. In the operation S421, the selection unit 613 waits for the execution command to be stored in the command buffer 611.

The virtual machine 600 then executes operations S422, S423. In the operation S422, the interlock unit 614 sets the entry prohibited area of the corresponding machine body 10 in the virtual space based on the progress of the task performed by the other machine body 10. In the operation S423, based on the execution condition (the condition header 422) of each of the plurality of tasks in the task program storage unit 612 and the state of the virtual space stored in the interlock unit 614, the selection unit 613 checks whether any of the tasks (the corresponding tasks) corresponding to the execution command stored in the command buffer 611 is executable. If it is determined in the operation S423 that there is no executable corresponding task, the virtual machine 600 returns the processing to the operation S421.

If it is determined in the operation S423 that there is a corresponding task that is executable, the virtual machine 600 executes an operation S424. In the operation S424, the selection unit 613 selects a corresponding task that can be performed. If two or more corresponding tasks are executable, the selection unit 613 selects the corresponding task with the highest priority.

The virtual machine 600 then executes operations S425, S426. In the operation S425, the control unit 616 starts causing the machine body 10 to perform the corresponding task selected by the selection unit 613 in the virtual space. In the operation S426, the status output unit 617 sends the status information of the machine body 10 in the virtual space to the virtual host controller 500.

The virtual machine 600 then executes an operation S427. In the operation S427, the status output unit 617 checks whether the execution of the corresponding task is completed. If it is determined that the execution of the corresponding task is not completed, the virtual machine 600 returns the processing to the operation S426. Thereafter, the transmission of the status information of the machine body 10 in the virtual space to the virtual host controller 500 is repeated until the execution of the corresponding task is completed.

If it is determined in the operation S427 that the execution of the corresponding task is completed, the status output unit 617 executes an operation S428. In the operation S428, the status output unit 617 includes a completion notification of the corresponding task in status information and transmits the status information to the virtual host controller 500. The virtual machine 600 then returns the treatment to the operation S421. The virtual machine 600 repeatedly executes the above processing.

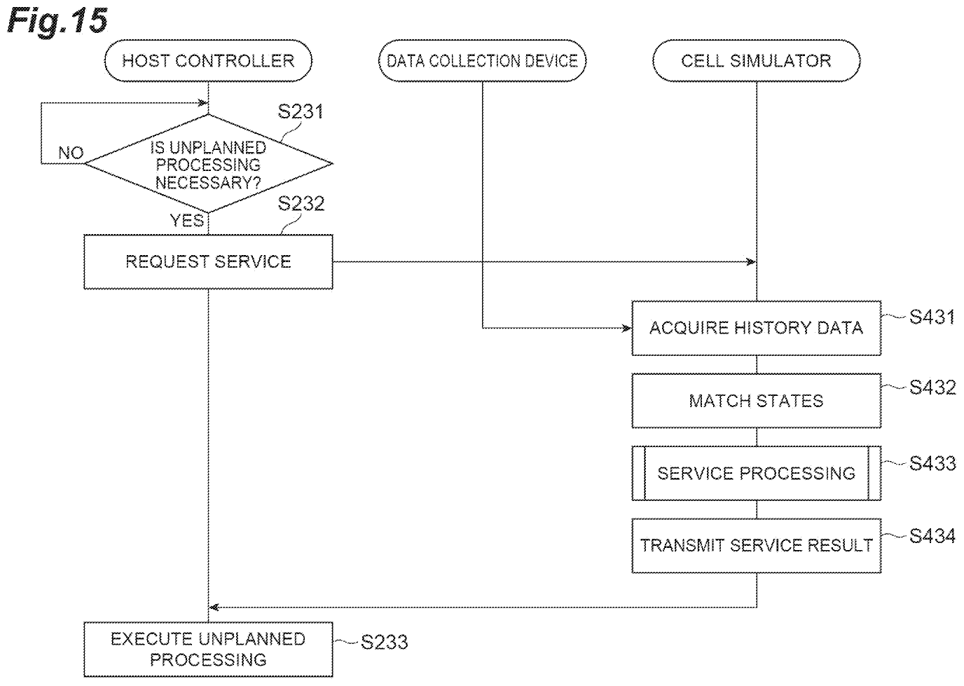

FIG. 15 is a flowchart illustrating an unplanned processing procedure by the production system 1. As illustrated in FIG. 15, the host controller 300 first performs an operation S231. In the operation S231, the host controller 300 waits for unplanned processing to be demanded. Examples of the unplanned process include the above-described recovery operation. For example, if the operation of the plurality of machines 5 is stopped due to the occurrence of an abnormality, the host controller 300 determines that the recovery operation should be generated.

The host controller 300 then executes an operation S232. In the operation S232, the host controller 300 requests a service for executing unplanned processing from the cell simulator 200. For example, the host controller 300 requests the cell simulator 200 to generate an unplanned processing to be performed by at least one of the plurality of machines 5.

In response to a request for service from the host controller 300, the cell simulator 200 executes operations S431, S432. In the operation S431, the state matching unit 213 acquires state information of the real space from the database 112. In the operation S432, the state matching unit 213 matches the state of the virtual space with the state of the real space based on the information acquired in the operation S431.

The cell simulator 200 then executes operations S433, S434. In the operation S433, the service unit 221 causes the virtual production device 212 to execute the on-demand simulation, and executes service processing for generating response information based on the result of the on-demand simulation. In the operation S434, the service unit 221 transmits the result of the service processing to the host controller 300 as the response information.

In response to receiving the service result, the host controller 300 executes an operation S233. In the operation S233, based on the response information, the host controller 300 causes at least one of the plurality of machines 5 to execute the unplanned processing. Thus, the unplanned processing procedure by the production system 1 is completed.

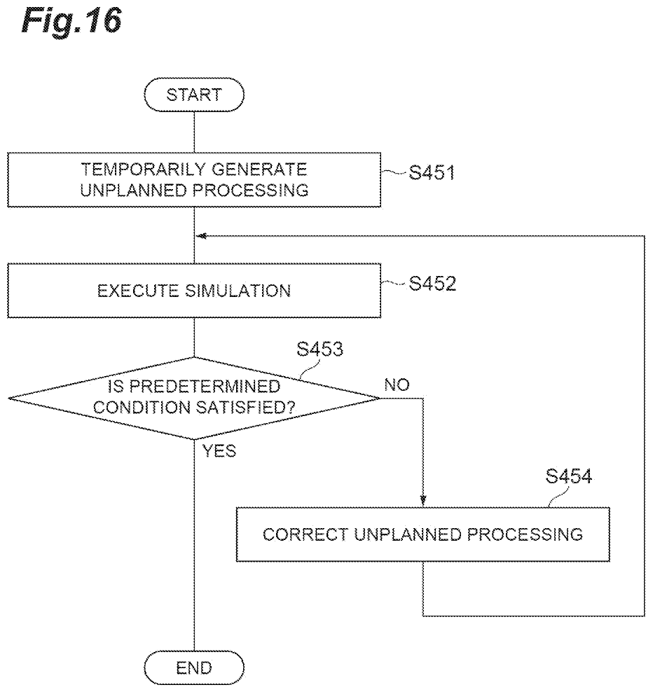

FIG. 16 is a flowchart illustrating a service processing procedure in the operation S S433. As illustrated in FIG. 16, the cell simulator 200 first executes operations S451, S452. In the operation S451, the service unit 221 temporarily generates unplanned processing. In the operation S452, the service unit 221 causes the virtual production device 212 to perform the unplanned processing in the virtual space.

The cell simulator 200 then executes an operation S453. In the operation S453, it is checked whether the operation result of the virtual production device 212 in the virtual space satisfies a predetermined condition. If it is determined in the operation S453 that the operation result of the virtual production device 212 in the virtual space does not satisfy the predetermined condition, the cell simulator 200 executes an operation S454. In the operation S454, the service unit 221 corrects the unplanned processing based on the operation result of the virtual production device 212 in the virtual space. The cell simulator 200 then returns the processing to the operation S452.

Thereafter, until the operation result of the virtual production device 212 in the virtual space satisfies the predetermined condition, the correction of the unplanned processing and the operation of the virtual production device 212 in the virtual space are repeated. If it is determined in the operation S453 that the operation result of the virtual production device 212 in the virtual space satisfies the predetermined condition, the cell simulator 200 completes the service processing.

### Summary

The above disclosure include the following configurations.
(1) A production system 1 including: a production device 4 configured to produce a product by executing processing on a workpiece in a real space based on a production instruction transmitted based on a production plan; a simulator 200 including a virtual production device 212 configured to perform a virtual processing corresponding to the processing performed by the production device 4 in a virtual space based on the production instruction; and a comparison unit 216 configured to compare an execution result of the processing with an execution result of the virtual processing.

Based on the same production instruction as the production instruction for the production device 4, the virtual processing is performed by the virtual production device 212 in the virtual space, the execution result of the virtual processing in accordance with the situation in which the production device 4 performs the processing is generated as a comparison reference, and the execution result of the processing can be monitored based on the comparison with the comparison reference.
(2) The production system 1 according to (1), wherein the simulator 200 further includes a state matching unit 213 configured to match a state of the virtual space with a state of the real space at a time of starting execution of the processing, and wherein the virtual production device 212 is configured to perform the virtual processing based on the state of the virtual space matched with the state of the real space. By matching the state of the virtual space with the state of the real space immediately before the execution of the processing corresponding to the production instruction and then causing the virtual production device 212 to perform the virtual processing, a comparison reference with reliability can be generated.
(3) The production system 1 according to (2), further including a history acquisition unit 111 configured to collect an execution history of the processing from the production device 4 and store the history in a database 112, wherein the state matching unit 213 is configured to match the state of the virtual space with the state of the real space based on information stored in the database 112.

According to the architecture in which the production device 4 stores the execution history of the processing in the database 112 and the state of the virtual cell is matched with the state of the cell based on the information stored in the database 112, a system in which the state of the virtual space is matched with the state of the real space immediately before the processing corresponding to the production instruction is performed may readily constructed, and then the virtual processing is performed by the virtual production device 212.
(4) The production system 1 according to any one of (1) to (3), wherein the production device 4 is configured to autonomously perform the processing with a predetermined algorithm based on the production instruction and the state of the real space, and wherein the virtual production device 212 is configured to autonomously perform the virtual processing with the algorithm based on the production instruction and the state of the virtual space.

A more reliable comparison reference can be generated by executing the virtual processing with the same algorithm as the algorithm of the production device 4 based on the same production instruction as the production instruction for the production device 4.
(5) The production system 1 according to (4), wherein the production device 4 includes: a plurality of machines 5 including robots 5B, 5C, 5D; and an information bulletin unit 315 configured to collect state information of the real state, and wherein the robots 5B, 5C, 5D are configured to autonomously perform at least a part of the processing based on the state information of the real space collected by the information bulletin unit 315.

If the robots 5B, 5C, 5D are caused to autonomously operate based on the production instruction and the state information of the cell, it is more difficult to specify the virtual processing to be performed by the virtual production device 212 to generate the comparison target. For this reason, comparison with a comparison target generated by simulation based on the production instruction is more useful.
(6) The production system 1 according to (5), wherein the information bulletin unit 315 is further configured to collect progress information of the processing, and the robots 5B, 5C, 5D are configured to autonomously perform at least a part of the processing based on the state information of the real space and the progress information.

If the robots 5B, 5C, 5D are caused to autonomously operate based on the progress information in addition to the production instruction and the state information of the cell, it is more difficult to specify the virtual processing to be performed by the virtual production device 212 to generate the comparison target. Accordingly, comparison with a comparison target generated by simulation based on the production instruction is more useful.
(7) The production system 1 according to (6), further including a process assignment unit 316 configured to assign an unperformed process in the processing to one of the plurality of machines 5 based on the progress information, wherein the robots 5B, 5C, 5D are configured to autonomously perform the process assigned by the process assignment unit 316 based on the state information of the real space.

If the assignment of the process based on the progress information is autonomously performed by the process assignment unit 316 for the plurality of machines 5, it is more difficult to specify the virtual processing to be executed by the virtual production device 212 in order to generate the comparison target. For this reason, comparison with a comparison target generated by simulation based on the production instruction is more useful.
(8) The production system 1 according to (6) or (7), wherein the robots 5B, 5C, 5D include an interlock unit 414 configured to set an entry prohibited area of the robots 5B, 5C, 5D based on progress of a process executed by one of the plurality of machines 5 other than the robots 5B, 5C, 5D.

Since the entry prohibited area of the robots 5B, 5C, 5D is dynamically generated based on the progress of the process executed by the machine 5 other than the robots 5B, 5C, 5D, the entry prohibited area of the robots 5B, 5C, 5D may not be set in advance in consideration of all situations. Accordingly, the production system 1 can readily be constructed. If the entry prohibited area is further autonomously set, it is more difficult to specify the virtual processing to be executed by the virtual production device 212 to generate the comparison target. Accordingly, comparison with a comparison target generated by simulation based on the production instruction is more useful.
(9) The production system 1 according to (8), wherein the progress information includes reservation information indicating which of the plurality of machines 5 is allocated to an unperformed process, wherein the information bulletin unit 315 is configured to prohibit allocation of another machine 5 to a proces to which one of the plurality of machines 5 is allocated in the reservation information, and wherein each of the plurality of machines 5 is configured to perform a process assigned in the reservation information.

Based on the reservation information, the setting of the entry prohibited area can timely be executed. In addition, based on the reservation information, the autonomous operation of each of the plurality of machines 5 can timely be executed.

(10) The production system 1 according to any one of (5) to (9), further including a display unit 318 configured to display the information collected by the information bulletin unit 315 on a monitor.

Accordingly, an operator can readily grasp the state on which an autonomously performed operation of the robots 5B, 5C, 5D is based.

(11) The production system 1 according to any one of (5) to (10), wherein the virtual production device 212 includes: a plurality of virtual machines 600 including a virtual robot corresponding to the robots 5B, 5C, 5D; and a virtual information bulletin unit 515 configured to collect state information of the virtual space, and wherein the virtual robot is configured to autonomously perform at least a part of the virtual processing based on the state information of the virtual space collected by the virtual information bulletin unit 515.

By matching the virtual production device 212 configuration with the production device 4 configuration, a more reliable comparison target can be generated.
(12) The production system 1 according to (11), further including: a factor identification unit 223 configured to, if a comparison result by the comparison unit 216 includes a deviation between an execution result of at least a part of the processing by the robots 5B, 5C, 5D and an execution result of at least a part of the virtual processing by the virtual robot, specify the virtual machine 600 other than the robots 5B, 5C, 5D as a factor of the deviation; and a simulator correction unit 222 configured to correct a simulation parameter for causing the virtual machine 600 that is the factor of the deviation to perform at least a part of the virtual processing.

Reliability of the comparison target generated by the simulation can be further improved.
(13) The production system 1 according to any one of (2) to (12), wherein the comparison unit 216 is configured to compare a transition timing of the state of the real space in accordance with progress of the processing with a transition timing of the state of the virtual space in accordance with progress of the virtual processing.

The ease of use of the comparison result between the execution result of the processing and the execution result of the virtual processing may be improved.
(14) The production system 1 according to any one of (1) to (13), wherein the simulator 200 further includes a service unit 221 configured to cause the virtual production device 212 to perform an on-demand simulation in response to a request from the production device 4 and return response information based on a result of the on-demand simulation to the production device 4.

According to the simulator 200 that causes the virtual production device 212 to perform the virtual processing based on the production instruction for the production device 4, the state of the virtual cell transitions together with the state of the cell. Accordingly, the on-demand simulation corresponding to the request from the production device 4 can be promptly performed based on the state of the virtual cell transitioned together with the state of the cell, and the response information can be returned to the production device 4 with a short standby time.
(15) The production system 1 according to any one of (1) to (14), further including a parameter changing unit 321 configured to change a control parameter for causing the production device 4 to perform the processing so as to reduce a deviation between an execution result of the processing and an execution result of the virtual processing based on a comparison result by the comparison unit 216.

The comparison result by the comparison unit 216 can be used to adjust the control parameter.
(16) The production system 1 according to any one of (1) to (15), further including a simulator correction unit 222 configured to change a simulation parameter for causing the virtual production device 212 to perform the virtual processing so as to reduce a deviation between an execution result of the processing and an execution result of the virtual processing based on a comparison result by the comparison unit 216.

The comparison result by the comparison unit 216 can be used to adjust the simulation parameter.
(17) The production system 1 according to any one of (1) to (16), further including a plan changing unit 811 configured to change the production plan based on a comparison result by the comparison unit 216. The comparison result by the comparison unit 216 can be used to adjust the production plan.
(18) The production system 1 according to any one of (1) to (17), wherein the simulator 200 further includes: an API 224 configured to operate the virtual production device 212 based on a simulation instruction; and the command conversion unit 225 configured to receive the production instruction and convert the production instruction into the simulation instruction.

The simulator 200 causing the virtual production device 212 to perform the virtual processing based on the same production instruction as a production instruction to the production device 4 can readily be constructed.
(19) A production method including: producing a product by executing processing on a workpiece in a real space based on a production instruction transmitted based on a production plan; causing a virtual production device 212 to perform a virtual processing corresponding to the processing performed by the production device 4 in a virtual space based on the production instruction; and comparing an execution result of the processing with an execution result of the virtual processing.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A production system, comprising:
a production device configured to perform, to produce a product, processing on a workpiece in a real space in response to a production instruction transmitted based on a production plan; and
simulation circuitry configured to:
cause a virtual production device to perform, in a virtual space, virtual processing corresponding to the processing in response to the transmitted production instruction; and
compare an execution result of the processing with an execution result of the virtual processing.

2. The production system according to claim 1, wherein the simulation circuitry is further configured to:
match a state of the virtual space with a state of the real space at a time of starting execution of the processing; and
cause the virtual production device to perform the virtual processing based on the state of the virtual space matched with the state of the real space.

3. The production system according to claim 2, wherein the simulation circuitry is further configured to:
collect an execution history of the processing from the production device and store the execution history in a database; and
match the state of the virtual space with the state of the real space based on the execution history stored in the database.

4. The production system according to claim 1, wherein the production device is configured to autonomously perform the processing with a predetermined algorithm based on the transmitted production instruction and a state of the real space, and
wherein the simulation circuitry is configured to cause the virtual production device to autonomously perform the virtual processing with the algorithm based on the transmitted production instruction and a state of the virtual space.

5. The production system according to claim 4, wherein the production device comprises:
a plurality of machines including a robot; and
an information bulletin storage configured to store collected information of the real space, and
wherein the robot is configured to autonomously perform at least one process of the processing based on information of the state of the real space stored in the information bulletin storage.

6. The production system according to claim 5, wherein the information bulletin storage is further configured to store collected progress information of the processing, and
wherein the robot is configured to autonomously perform at least a part of the processing based on the state of the real space and the progress information.

7. The production system according to claim 6, further comprising control circuitry configured to assign an unperformed process that is a part of the processing to one of the plurality of machines based on the progress information,
wherein the robot is configured to autonomously perform the at least one process assigned by the control circuitry based on the state of the real space.

8. The production system according to claim 6, wherein the robot is configured to set an entry prohibited area of the robot based on progress of one or more processes performed by one or more of the plurality of machines other than the robot.

9. The production system according to claim 8, wherein the progress information includes reservation information indicating which of the plurality of machines is allocated to an unperformed process,
wherein the circuitry is configured to prohibit allocation of another machine to the unperformed process to which one of the plurality of machines is allocated in the reservation information, and
wherein each of the plurality of machines is configured to perform a process assigned in the reservation information.

10. The production system according to claim 5, further comprising a display device configured to display the information stored in the information bulletin storage.

11. The production system according to claim 5, wherein the virtual production device comprises:
a plurality of virtual machines including a virtual robot corresponding to the robot; and
a virtual information bulletin storage configured to store collected information of the virtual space, and
wherein the simulation circuitry is configured to cause the virtual robot to autonomously perform at least one virtual process of the virtual processing that corresponds to the at least one process of the robot based on the state of the virtual space stored in the virtual information bulletin storage.

12. The production system according to claim 11, wherein the simulation circuitry is further configured to:
specify, in response to detecting a deviation between the execution result of the at least one process by the robot and the execution result of the at least one virtual process by the virtual robot, a virtual machine other than the robot as a factor of the deviation; and
correct a simulation parameter for causing the virtual machine that corresponds to the factor of the deviation to perform a process of the virtual processing.

13. The production system according to claim 2, wherein the simulation circuitry is configured to compare a transition timing of the state of the real space in accordance with progress of the processing with a transition timing of the state of the virtual space in accordance with progress of the virtual processing.

14. The production system according to claim 1, wherein the simulation circuitry is further configured to cause the virtual production device to perform an on-demand simulation in response to a request from the production device and return response information based on a result of the on-demand simulation to the production device.

15. The production system according to claim 1, further comprising control circuitry configured to change a control parameter for causing the production device to perform the processing so as to reduce a deviation between an execution result of the processing and an execution result of the virtual processing based on a comparison result by the simulation circuitry.

16. The production system according to claim 1, wherein the simulation circuitry is further configured to change a simulation parameter for causing the virtual production device to perform the virtual processing so as to reduce a deviation between an execution result of the processing and an execution result of the virtual processing based on a comparison result by the simulation circuitry.

17. The production system according to claim 1, further comprising planning circuitry configured to change the production plan based on a comparison result by the simulation circuitry.

18. The production system according to claim 1, wherein the simulation circuitry comprises an application programming interface (API) configured to receive a simulation instruction for operating the virtual production device, and
wherein the simulation circuitry is further configured to:
convert the transmitted production instruction into the simulation instruction; and
operate the virtual production device according to the simulation instruction received via the API.

19. The production system according to claim 1, wherein the simulation circuitry is configured to cause the virtual production device to perform the virtual processing in response to the transmitted production instruction during the production device executing the processing in response to the transmitted production instruction.

20. A production method comprising:
executing, to produce a product, processing on a workpiece in a real space in response to a production instruction transmitted based on a production plan;
causing a virtual production device to perform, in a virtual space, virtual processing corresponding to the processing in response to the transmitted production instruction; and
comparing an execution result of the processing with an execution result of the virtual processing.
